(19) United States
(12) Patent Application Publication
(10) Pub. No.: US 2026/0081578 A1
(43) Pub. Date: Mar. 19, 2026

(54) ACOUSTIC WAVE DEVICE

(71) Applicant: Murata Manufacturing Co., Ltd., Nagaokakyo-shi (JP)

(72) Inventor: Katsuya DAIMON, Nagaokakyo-shi (JP)

(21) Appl. No.: 19/395,272

(22) Filed: Nov. 20, 2025

Related U.S. Application Data
(63) Continuation of application No. PCT/JP2024/015370, filed on Apr. 18, 2024.

(30) Foreign Application Priority Data
May 29, 2023 (JP) 2023-087881

(51) Int. Cl. H03H 9/13; H03H 9/15

(52) U.S. Cl. CPC H03H 9/13; H03H 9/15

(57) ABSTRACT

An acoustic wave device includes a support substrate, a piezoelectric layer on the support substrate, and at least one lithium niobate layer and first and second principal surfaces opposed to each other, and first and second IDT electrodes respectively on the first and second principal surfaces. Each of the first and second IDT electrodes includes electrode fingers. A duty ratio of each of the first and second IDT electrodes is equal to or greater than about 0.6. Directions of polarization of the piezoelectric layer are inverted in a thickness direction of the piezoelectric layer.

### CROSS REFERENCE TO RELATED APPLICATIONS

This application claims the benefit of priority to Japanese Patent Application No. 2023-087881 filed on May 29, 2023 and is a Continuation Application of PCT Application No. PCT/JP2024/015370 filed on Apr. 18, 2024. The entire contents of each application are hereby incorporated herein by reference.

### BACKGROUND OF THE INVENTION

### 1. Field of the Invention

The present invention relates to acoustic wave devices.

### 2. Description of the Related Art

Acoustic wave devices have heretofore been widely used for filters in mobile phones and the like. Japanese Unexamined Patent Application Publication No. 2021-118366 discloses an example of a surface acoustic wave filter as an acoustic wave device. In this surface acoustic wave filter, a LiTaO₃ substrate is provided on a support substrate. IDT (interdigital transducer) electrodes are provided on the LiTaO₃ substrate. A third harmonic wave is used to operate the surface acoustic wave filter described in Japanese Unexamined Patent Application Publication No. 2021-118366.

In the surface acoustic wave filter described in Japanese Unexamined Patent Application Publication No. 2021-118366, a fundamental wave is strongly excited besides the third harmonic wave. However, the fundamental wave becomes an unnecessary wave in the case of using the third harmonic wave to operate the surface acoustic wave filter. That is to say, the above-described surface acoustic wave filter cannot sufficiently suppress the unnecessary wave.

### SUMMARY OF THE INVENTION

Example embodiments of the present invention provide acoustic wave devices, each able to excite a third harmonic wave and reduce or prevent a fundamental wave.

An acoustic wave device according to an example embodiment of the present invention includes a support substrate, a piezoelectric layer on the support substrate, and including at least one lithium niobate layer, and a first principal surface and a second principal surface opposed to each other, a first interdigital transducer (IDT) electrode on the first principal surface of the piezoelectric layer, and a second IDT electrode on the second principal surface of the piezoelectric layer, each of the first IDT electrode and the second IDT electrode includes a plurality of electrode fingers and a duty ratio of each of the first IDT electrode and the second IDT electrode is equal to or greater than about 0.6, and directions of polarization of the piezoelectric layer are inverted in a thickness direction of the piezoelectric layer.

According to example embodiments of the present invention, acoustic wave devices, each able to excite a third harmonic wave and reduce or prevent a fundamental wave, are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic elevational sectional view of an acoustic wave device according to a first example embodiment of the present invention.

FIG. 2 is a schematic bottom view of the acoustic wave device according to the first example embodiment of the present invention.

FIG. 3 is a schematic elevational sectional view showing part of the acoustic wave device according to the first example embodiment of the present invention.

FIG. 4 is a diagram showing impedance frequency characteristics of the first example embodiment of the present invention and of a comparative example.

FIG. 5 is a diagram showing a relationship between duty ratios of a first IDT electrode as well as a second IDT electrode and an impedance ratio of a third harmonic wave.

FIG. 6 is a diagram showing the impedance frequency characteristics in a case where the duty ratio of each of the first IDT electrode and the second IDT electrode is about 0.8 in the acoustic wave device having design parameters with the relationship of FIG. 5.

FIG. 7 is a diagram showing a relationship between a second Euler angle θ1 of a first lithium niobate layer and the impedance ratio of the third harmonic wave.

FIG. 8 is a diagram showing a relationship between a thickness of a piezoelectric layer and the impedance ratio of the third harmonic wave.

FIG. 9 is a diagram showing the impedance frequency characteristics in a case where a thickness ratio between the first lithium niobate layer and a second lithium niobate layer is about 2.33.

FIG. 10 is a diagram showing the impedance frequency characteristics in a case where the thickness ratio between the first lithium niobate layer and the second lithium niobate layer is about 1.5.

FIG. 11 is a diagram showing the impedance frequency characteristics in a case where the thickness ratio between the first lithium niobate layer and the second lithium niobate layer is about 1.

FIG. 12 is a diagram showing the impedance frequency characteristics in a case where the thickness ratio between the first lithium niobate layer and the second lithium niobate layer is about 0.67.

FIG. 13 is a diagram showing the impedance frequency characteristics in a case where the thickness ratio between the first lithium niobate layer and the second lithium niobate layer is about 0.43.

FIG. 14 is a diagram showing the impedance frequency characteristics in a case where the thickness ratio between the first lithium niobate layer and the second lithium niobate layer is about 0.25.

FIG. 15 is a diagram showing a relationship between a thickness of main electrode layers in the first IDT electrode and the second IDT electrode, and the impedance ratio of the third harmonic wave.

FIG. 16 is a diagram showing a relationship between the thickness of the main electrode layer in the first IDT electrode and the impedance ratio of the third harmonic wave.

FIG. 17 is a diagram showing the impedance frequency characteristics in a case where the main electrode layer in the first IDT electrode is a Pt layer and in a case where the layer is an Al layer.

FIG. 18 is a diagram showing a relationship between a third Euler angle of a support substrate and a phase in a high-order mode in a case where a plane orientation of the support substrate is (111).

FIG. 19 is a diagram showing the relationship between the third Euler angle of the support substrate and the phase in the high-order mode in a case where the plane orientation of the support substrate is (110).

FIG. 20 is a schematic elevational sectional view of an acoustic wave device according to a second example embodiment of the present invention.

FIG. 21 is a schematic plan view of an acoustic wave device according to a third example embodiment of the present invention.

FIG. 22 is a schematic sectional view taken along line II-II in FIG. 21.

FIGS. 23A to 23E are schematic sectional views taken along a direction of extension of electrode fingers to explain steps until a step of providing a second layer of an intermediate layer in an example of a method of manufacturing the acoustic wave device according to the third example embodiment of the present invention.

FIGS. 24A to 24C are schematic sectional views taken along the direction of extension of the electrode fingers to explain steps until a step of providing the intermediate layer in the example of the method of manufacturing the acoustic wave device according to the third example embodiment of the present invention.

FIGS. 25A to 25C are schematic sectional views taken along the direction of extension of the electrode fingers to explain steps until a step of providing the second IDT electrode in the example of the method of manufacturing the acoustic wave device according to the third example embodiment of the present invention.

FIGS. 26A and 26B are schematic sectional views taken along the direction of extension of the electrode fingers to explain steps until a step of providing a conducting portion in the example of the method of manufacturing the acoustic wave device according to the third example embodiment of the present invention.

FIGS. 27A to 27F are schematic sectional views taken along the direction of extension of the electrode fingers to explain steps until a step of providing the second layer of the intermediate layer in an example of the method of manufacturing the acoustic wave device using a temporary substrate according to the third example embodiment of the present invention.

FIGS. 28A and 28B are schematic sectional views taken along the direction of extension of the electrode fingers to explain steps until a step of removing the temporary substrate in the example of the method of manufacturing the acoustic wave device using the temporary substrate according to the third example embodiment of the present invention.

FIG. 29 is a schematic sectional view taken along the direction of extension of the electrode fingers of an acoustic wave device according to a first modification of the third example embodiment of the present invention.

FIGS. 30A to 30C are schematic sectional views taken along the direction of extension of the electrode fingers to explain steps until a step of providing the first IDT electrode in an example of a method of manufacturing the acoustic wave device according to the first modification of the third example embodiment of the present invention.

FIG. 31 is a schematic sectional view taken along the direction of extension of the electrode fingers to explain a step of providing the piezoelectric layer with a through hole in the example of the method of manufacturing the acoustic wave device according to the first modification of the third example embodiment of the present invention.

FIG. 32 is a schematic sectional view taken along the direction of extension of the electrode fingers of an acoustic wave device according to a second modification of the third example embodiment of the present invention.

FIG. 33 is a schematic sectional view taken along the direction of extension of the electrode fingers to explain a step of providing the piezoelectric layer with a through hole in an example of a method of manufacturing the acoustic wave device according to the second modification of the third example embodiment of the present invention.

FIG. 34 is a schematic sectional view taken along the direction of extension of the electrode fingers of an acoustic wave device according to a third modification of the third example embodiment of the present invention.

FIG. 35 is a schematic sectional view taken along the direction of extension of the electrode fingers to explain a step of bonding a first layer and a second layer in an example of a method of manufacturing the acoustic wave device according to the third modification of the third example embodiment of the present invention.

### DETAILED DESCRIPTION OF THE EXAMPLE EMBODIMENTS

The present invention will be clarified by describing example embodiments of the present invention below with reference to the drawings.

The respective example embodiments described in the present specification are exemplary. Partial replacement or combination among different example embodiments is possible.

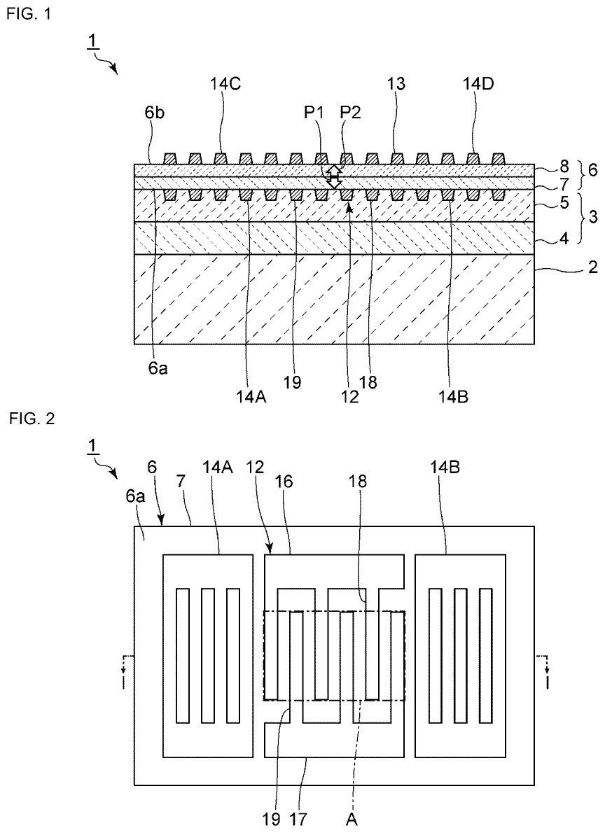

FIG. 1 is a schematic elevational sectional view of an acoustic wave device according to a first example embodiment of the present invention. FIG. 2 is a schematic bottom view of the acoustic wave device according to the first example embodiment. Here, FIG. 1 is a schematic sectional view taken along line I-I in FIG. 2.

As shown in FIG. 1, an acoustic wave device 1 includes a support substrate 2, an intermediate layer 3, and a piezoelectric layer 6. The intermediate layer 3 is provided on the support substrate 2. The piezoelectric layer 6 is provided on the intermediate layer 3. The piezoelectric layer 6 is a layer including a material having piezoelectricity. Accordingly, the piezoelectric layer 6 has piezoelectricity.

The piezoelectric layer 6 includes a first lithium niobate layer 7 and a second lithium niobate layer 8. The second lithium niobate layer 8 is directly laminated on the first lithium niobate layer 7. Here, of the first lithium niobate layer 7 and the second lithium niobate layer 8, the first lithium niobate layer 7 is located on the support substrate 2 side. Accordingly, in the acoustic wave device 1, the support substrate 2, the intermediate layer 3, the first lithium niobate layer 7, and the second lithium niobate layer 8 are laminated in this order. Nonetheless, the piezoelectric layer 6 only needs to include at least one lithium niobate layer.

The piezoelectric layer 6 includes a first principal surface 6a and a second principal surface 6b. The first principal surface 6a and the second principal surface 6b are opposed to each other. The first principal surface 6a is included in the first lithium niobate layer 7. The second principal surface 6b is included in the second lithium niobate layer 8.

Rotated Y-cut lithium niobate is used for each of the first lithium niobate layer 7 and the second lithium niobate layer 8, for example. Nonetheless, lithium niobate used for the first lithium niobate layer 7 and the second lithium niobate layer 8 is not limited to the above-described material.

In the present example embodiment, the intermediate layer 3 is a multilayer body. Specifically, the intermediate layer 3 includes a first layer 4 and a second layer 5. More specifically, the first layer 4 is provided on the support substrate 2. The second layer 5 is provided on the first layer 4. The piezoelectric layer 6 is provided on the second layer 5.

As described above, the piezoelectric layer 6 is provided indirectly on the support substrate 2 with the intermediate layer 3 interposed therebetween. The intermediate layer 3 does not always have to be provided. The piezoelectric layer 6 may be directly provided on the support substrate 2.

Silicon nitride and silicon oxide, for example, are used as materials of the intermediate layer 3. Specifically, for example, silicon nitride is used as a material of the first layer 4, and silicon oxide is used as a material of the second layer 5.

In the present invention, the intermediate layer 3 may be a single-layered dielectric layer. In this case, silicon nitride or silicon oxide may be used as the material of the single-layered intermediate layer 3, for example. Nonetheless, the material of the intermediate layer 3 is not limited to the above-described materials.

Specifically, the support substrate 2 is, for example, a silicon substrate. A plane orientation of the support substrate 2 is, for example, (111). More specifically, the plane orientation of a surface on the piezoelectric layer 6 side of the support substrate 2 is, for example, (111). When Euler angles of the support substrate 2 are assumed to be (φ_{Si}, θ_{Si}, ψ_{Si}), the value ψ_{Si} in the Euler angles of the support substrate 2 is in a range of about 60°±10°, for example. Nonetheless, the Euler angles and the plane orientation of the support substrate 2 are not limited to the foregoing. The material of the support substrate 2 is not limited to silicon either. For example, ceramics such as aluminum oxide may also be used as the material of the support substrate 2.

In FIG. 1, a direction of polarization of the first lithium niobate layer 7 is indicated with an arrow P1. A direction of polarization of the second lithium niobate layer 8 is indicated with an arrow P2. The direction of polarization of the first lithium niobate layer 7 and the direction of polarization of the second lithium niobate layer 8 are mutually opposite directions. More specifically, in the present example embodiment, the directions of polarization are inverted in a thickness direction of the piezoelectric layer 6.

Here, in arbitrary Euler angles (φ, θ, ψ), the value φ is a first Euler angle, the value θ is a second Euler angle, and the value ψ is a third Euler angle. In the present specification, the directions of polarization being inverted at two portions means that a difference in second Euler angle θ at the two portions is in a range within about 180°+5°, for example. In the present invention, when the Euler angles of the first lithium niobate layer 7 are assumed to be (φ1, θ1, ψ1) and the Euler angles of the second lithium niobate layer 8 are assumed to be (φ2, θ2, ψ2), the difference between the second Euler angle θ1 and the second Euler angle θ2 is in the range within about 180°±5°, for example. Moreover, the difference in second Euler angles θ between the first principal surface 6a and the second principal surface 6b of the piezoelectric layer 6 is in the range within about 180°±5°, for example.

A first IDT electrode 12 is provided on the first principal surface 6a of the piezoelectric layer 6. Thus, the first IDT electrode 12 is provided on a principal surface of the first lithium niobate layer 7. Meanwhile, a second IDT electrode 13 is provided on the second principal surface 6b of the piezoelectric layer 6. Thus, the second IDT electrode 13 is provided on a principal surface of the second lithium niobate layer 8. The first IDT electrode 12 and the second IDT electrode 13 are opposed to each other with the piezoelectric layer 6 interposed therebetween.

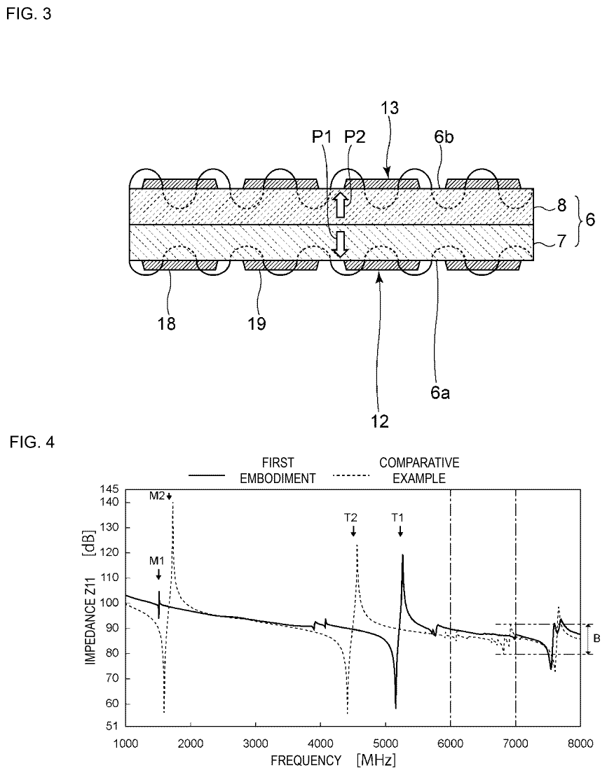

FIG. 3 is a schematic elevational sectional view showing a portion of the acoustic wave device according to the first example embodiment. The intermediate layer and the like are omitted in FIG. 3.

An acoustic wave is excited by applying an alternating-current voltage to the first IDT electrode 12. Similarly, an acoustic wave is excited by applying an alternating-current voltage to the second IDT electrode 13. The acoustic wave device 1 is configured to be capable of using a third harmonic wave. A fundamental wave becomes an unnecessary wave in a case of using the third harmonic wave to operate the acoustic wave device 1. The third harmonic wave is schematically illustrated in FIG. 3. Here, positive displacement of the third harmonic wave is indicated with a solid line and negative displacement thereof is indicated with a dashed line in FIG. 3.

As shown in FIG. 2, the first IDT electrode 12 includes a pair of busbars and multiple electrode fingers. Specifically, the pair of busbars include a first busbar 16 and a second busbar 17. The first busbar 16 and the second busbar 17 are opposed to each other. Specifically, the multiple electrode fingers include multiple first electrode fingers 18 and multiple second electrode fingers 19. One end of each of the multiple first electrode fingers 18 is connected to the first busbar 16. One end of each of the multiple second electrode fingers 19 is connected to the second busbar 17. The multiple first electrode fingers 18 and the multiple second electrode fingers 19 are interdigitated with one another. Each first electrode finger 18 and each second electrode finger 19 are connected to electric potentials that are different from each other.

Similarly, the second IDT electrode 13 shown in FIG. 1 also includes a pair of busbars and multiple electrode fingers. The first IDT electrode 12 and the second IDT electrode 13 may each include a single-layer metal film or include laminated metal films.

In each of the first IDT electrode 12 and the second IDT electrode 13, a direction of extension of the multiple electrode fingers is orthogonal or substantially orthogonal to a direction of propagation of the acoustic wave. As shown in FIG. 2, a region in the first IDT electrode 12 where the adjacent electrode fingers overlap one another is an intersecting region A. Similarly, the second IDT electrode 13 shown in FIG. 1 also includes an intersecting region. Here, each of the intersecting regions of the first IDT electrode 12 and the second IDT electrode 13 includes a central region. The central region is, for example, a region accounting for about 80% at the center in the direction of extension of the multiple electrode fingers in the intersecting region.

In the following description, a wavelength to be defined by an electrode finger pitch of the first IDT electrode 12 is assumed to be λ1. The electrode finger pitch is a center-to-center distance in the direction of propagation of the acoustic wave between the first electrode finger 18 and the second electrode finger 19 located adjacent to each other. For example, λ1=2p is satisfied when the electrode finger pitch is assumed to be p. The wavelength λ1 defined by the electrode finger pitch of the first IDT electrode 12 is a wavelength of the fundamental wave to be excited by applying an alternating-current voltage to the first IDT electrode 12. Similarly, a wavelength defined by the electrode finger pitch will be denoted as λ2 in the second IDT electrode 13 as well. The wavelength λ2 defined by the electrode finger pitch of the second IDT electrode 13 is a wavelength of the fundamental wave to be excited by applying an alternating-current voltage to the second IDT electrode 13.

In the present example embodiment, the electrode finger pitches of the first IDT electrode 12 and the second IDT electrode 13 are equal or substantially equal. Thus, λ1=λ2 is satisfied. In the present specification, the state where the electrode finger pitches are equal includes a state where the electrode finger pitches are different within such an error range that does not affect electric characteristics of the acoustic wave device.

A duty ratio of each of the first IDT electrode 12 and the second IDT electrode 13 is equal to or greater than about 0.6, for example. In the present example embodiment, the duty ratios of the first IDT electrode 12 and the second IDT electrode 13 are equal. In the present specification, the state where the duty ratios are equal includes a state where the duty ratios are different within such an error range that does not affect the electric characteristics of the acoustic wave device.

Here, the duty ratio is a metallization ratio in the region where the multiple electrode fingers are provided. Specifically, the duty ratio is a proportion of a portion covered by a metal of the electrode fingers on an imaginary line equivalent to one wavelength extending in the direction of propagation of the acoustic wave relative to the region where the multiple electrode fingers are provided. The duty ratio of the first IDT electrode 12 may be based on the wavelength λ1 defined by the electrode finger pitch of the first IDT electrode 12. The duty ratio of the second IDT electrode 13 may be based on the wavelength λ2 defined by the electrode finger pitch of the second IDT electrode 13.

The duty ratio of the IDT electrode in the present specification is the duty ratio measured at a certain portion in the central region unless otherwise stated. Nonetheless, the duty ratio of the first IDT electrode 12 in the present example embodiment is constant even when it is measured at any portion in the central region. The duty ratio of the first IDT electrode 12 in the present example embodiment is equal to that measured in the central region even in a case where it is measured at a portion in the intersecting region other than the central region. The same applies to the second IDT electrode 13 in the present example embodiment.

Characteristics of the present example embodiment are provided by the following configurations: 1) to include the piezoelectric layer 6 including at least one layer of a lithium niobate layer, the first IDT electrode 12 provided on the first principal surface 6a of the piezoelectric layer 6, and the second IDT electrode 13 provided on the second principal surface 6b thereof; 2) that the duty ratio of each of the first IDT electrode 12 and the second IDT electrode 13 is equal to or greater than about 0.6; and 3) that the directions of polarization of the piezoelectric layer 6 are inverted in the thickness direction of the piezoelectric layer 6. Thus, the third harmonic wave can be excited and the fundamental wave can be reduced or prevented. Accordingly, it is possible to use the third harmonic wave suitably to operate the acoustic wave device 1, and to reduce or prevent the fundamental wave as the unnecessary wave. This will be demonstrated below by comparing the present example embodiment with a comparative example.

The comparative example is different from the first example embodiment in that the piezoelectric layer is a single-layered lithium tantalate layer and that the directions of polarization of the piezoelectric layer are not inverted in the thickness direction. Impedance frequency characteristics were compared between the first example embodiment and the comparative example. Here, design parameters of the acoustic wave device 1 of the first example embodiment in this comparison are as follows:
Support substrate: material . . . Si, plane orientation . . . (111), third Euler angle ψ_{Si} . . . about 60°;
First layer of intermediate layer: material . . . SiN, thickness . . . about 400 nm;
Second layer of intermediate layer: material . . . SiO₂, thickness . . . about 300 nm;
First lithium niobate layer: material . . . rotated Y-cut LiNbO₃, Euler angles (φ1, θ1, ψ1) . . . (0°, 120°, 0°);
Second lithium niobate layer: material . . . rotated Y-cut LiNbO₃, Euler angles (φ2, θ2, ψ2) . . . (0°, −60°, 0°);
First IDT electrode: material . . . Al, thickness . . . 70 nm, wavelength λ1 . . . about 2.7 μm, duty ratio . . . about 0.8; and
Second IDT electrode: material . . . Al, thickness . . . 70 nm, wavelength λ2 . . . about 2.7 μm, duty ratio . . . about 0.8.

FIG. 4 is a diagram showing the impedance frequency characteristics of the first example embodiment and of the comparative example. An arrow M1 in FIG. 4 indicates a neighborhood of the frequency of the fundamental wave in the first example embodiment. An arrow M2 indicates a neighborhood of the frequency of the fundamental wave in the comparative example. An arrow T1 indicates a neighborhood of the frequency of the third harmonic wave in the first example embodiment. An arrow T2 indicates a neighborhood of the frequency of the third harmonic wave in the comparative example.

As shown in FIG. 4, the third harmonic wave can be strongly excited and the fundamental wave can be reduced or prevented in the first example embodiment. Accordingly, it is possible to suitably use the third harmonic wave to operate the acoustic wave device 1 and to reduce or prevent the fundamental wave as the unnecessary wave. On the other hand, in the comparative example, the third harmonic wave is excited but the fundamental wave is strongly excited as well.

In the acoustic wave device 1 shown in FIG. 1, the directions of polarization are inverted in the thickness direction of the piezoelectric layer 6. Accordingly, the fundamental wave excited by applying the alternating-current voltage to the first IDT electrode 12 can be offset with the fundamental wave excited by applying the alternating-current voltage to the second IDT electrode 13. Therefore, it is possible to reduce or prevent the fundamental wave. On the other hand, excitation of the third harmonic wave is less likely to be blocked.

In addition, the third harmonic wave can be strongly excited since the duty ratio is equal to or greater than about 0.6. Details of this factor will be shown below.

A relationship between the duty ratio and an impedance ratio of the third harmonic wave in the acoustic wave device having the same layer structure as that of the first example embodiment was evaluated. Specifically, the impedance ratio of the third harmonic wave was evaluated every time the duty ratio of each of the first IDT electrode and the second IDT electrode was changed. The impedance ratio is a value obtained by dividing impedance at an anti-resonant frequency by impedance at a resonant frequency. In the case where the impedance ratio of the third harmonic wave is high, the third harmonic wave is sufficiently excited. The design parameters of the acoustic wave device in this investigation are as follows. Here, the duty ratio of the first IDT electrode and the duty ratio of the second IDT electrode were set equal:
Support substrate: material . . . Si, plane orientation . . . (111), third Euler angle ψ_{Si} . . . about 73°;
First layer of intermediate layer: material SiN, thickness . . . about 300 nm;
Second layer of intermediate layer: material . . . SiO₂, thickness . . . about 200 nm;
First lithium niobate layer: material . . . rotated Y-cut LiNbO₃, Euler angles (φ1, θ1, ψ1) . . . (0°, 120°, 0°), thickness . . . about 250 nm;
Second lithium niobate layer: material . . . rotated Y-cut LiNbO₃, Euler angles (φ2, θ2, ψ2) . . . (0°, −60°, 0°), thickness . . . about 250 nm;

First IDT electrode: layer structure . . . Ti layer/Al layer from first lithium niobate layer side, thickness . . . about 12 nm/about 70 nm from first lithium niobate layer side, wavelength λ1 . . . about 2.7 μm, duty ratio . . . changed in increments of about 0.1 in a range from equal to or greater than about 0.2 to equal to or below about 0.9; and

Second IDT electrode: layer structure . . . Ti layer/Al layer from second lithium niobate layer side, thickness . . . about 12 nm/about 70 nm from second lithium niobate layer side, wavelength λ2 . . . about 2.7 μm, duty ratio . . . changed in increments of about 0.1 in the range from equal to or greater than about 0.2 to equal to or below about 0.9.

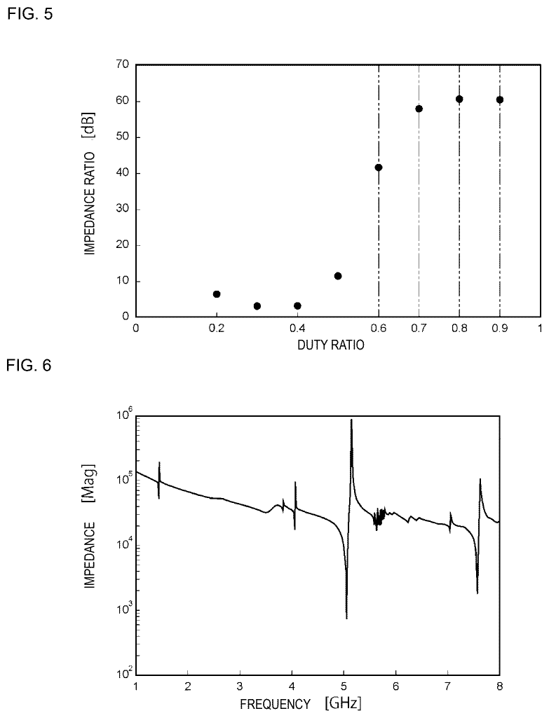

FIG. 5 is a diagram showing a relationship between the duty ratios of the first IDT electrode as well as the second IDT electrode and the impedance ratio of the third harmonic wave.

As shown in FIG. 5, it is evident that the impedance ratio of the third harmonic wave is considerably larger in the case where the duty ratio of each of the first IDT electrode and the second IDT electrode is equal to or greater than about 0.6 as compared to a case where the duty ratio is below about 0.6. Accordingly, in the first example embodiment shown in FIG. 1, it is possible to suitably excite the third harmonic wave by setting the duty ratio of each of the first IDT electrode 12 and the second IDT electrode 13 equal to or greater than about 0.6.

The duty ratio of each of the first IDT electrode 12 and the second IDT electrode 13 is, for example, preferably equal to or greater than about 0.7 or more preferably equal to or greater than about 0.8. In this way, the impedance ratio of the third harmonic wave can be increased effectively as shown in FIG. 5.

FIG. 6 is a diagram showing the impedance frequency characteristics in a case where the duty ratio of each of the first IDT electrode and the second IDT electrode is about 0.8 in the acoustic wave device having the design parameters that derived the relation of FIG. 5.

As shown in FIG. 6, it was discovered that the third harmonic wave is strongly excited in the case where the duty ratio of each of the first IDT electrode 12 and the second IDT electrode 13 is about 0.8. Similarly, the third harmonic wave can also be strongly excited in a case where the duty ratio of each of the first IDT electrode 12 and the second IDT electrode 13 exceeds about 0.8.

In the meantime, the duty ratio of each of the first IDT electrode 12 and the second IDT electrode 13 is, for example, preferably equal to or below about 0.9. The first IDT electrode 12 and the second IDT electrode 13 can be easily provided in this case.

In the comparative example in the comparison shown in FIG. 4, an unnecessary wave is generated on a higher range side than the third harmonic wave. Specifically, a mode representing the unnecessary wave is generated in a band equal to or greater than about 6000 MHz and equal to or below about 7000 MHz, for example. In FIG. 4, a difference between a minimum value and a maximum value of impedance in the mode generated at a frequency equal to or greater than about 6000 MHz and equal to or below about 7000 MHz in the comparative example is indicated with a double-sided arrow B. On the other hand, in the first example embodiment, this mode is reduced or prevented more as compared to the comparative example.

As in the first example embodiment, for example, the difference between the minimum value and the maximum value of the impedance in the mode generated at the frequency equal to or greater than about 6000 MHz and equal to or below about 7000 MHz is preferably equal to or below about 5 dB or more preferably equal to or below about 3 dB. Thus, it is possible to reduce or prevent deterioration of filter characteristics in a filter device in a case where the acoustic wave device 1 is used as the filter device.

A structure of the first example embodiment will be described below in more detail.

As described above, each of the first IDT electrode 12 and the second IDT electrode 13 shown in FIG. 1 includes the intersecting region. The intersecting region of the first IDT electrode 12 overlaps the intersecting region of the second IDT electrode 13 in plan view. More specifically, centers of the multiple electrode fingers in the intersecting region of the first IDT electrode 12 overlap centers of the multiple electrode fingers in the intersecting region of the second IDT electrode 13 in plan view. Nonetheless, at least a portion of the multiple electrode fingers of the first IDT electrode 12 only need to overlap at least a portion of the multiple electrode fingers of the second IDT electrode 13 in plan view. Here, the intersecting regions of the first IDT electrode 12 and the second IDT electrode 13 only need to overlap each other within such an error range that does not affect the electric characteristics of the acoustic wave device 1.

In the present specification, plan view means an act of viewing the acoustic wave device 1 from a direction corresponding to an upside in FIG. 1. In FIG. 1, of the piezoelectric layer 6 side and the support substrate 2 side, the piezoelectric layer 6 side is the upside.

In the first example embodiment, the first busbar 16 of the first IDT electrode 12 is connected to a signal potential. Accordingly, the multiple first electrode fingers 18 are connected to the signal potential. The second busbar 17 is connected to a ground potential. Accordingly, the multiple second electrode fingers 19 are connected to the ground potential. One of the busbars of the second IDT electrode 13 and the multiple electrode fingers connected to this busbar are connected to the signal potential. The other busbar of the second IDT electrode 13 and the multiple electrode fingers connected to this busbar are connected to the ground potential.

The electrode fingers of the first IDT electrode 12 and the second IDT electrode 13 connected to the signal potential overlap one another in plan view. On the other hand, the electrode fingers of the first IDT electrode 12 and the second IDT electrode 13 connected to the ground potential overlap one another in plan view. Here, one of the busbars of each of the IDT electrodes may be connected to an input side at the signal potential and the other busbar may be connected to an output side at the signal potential.

As shown in FIG. 1, a reflector 14A and a reflector 14B defining a pair are provided on two sides in the direction of propagation of the acoustic wave of the first IDT electrode 12 at the first principal surface 6a of the piezoelectric layer 6. Similarly, a reflector 14C and a reflector 14D defining a pair are provided on two sides in the direction of propagation of the acoustic wave of the second IDT electrode 13 at the second principal surface 6b. Each of the reflectors provided on the first principal surface 6a and the second principal surface 6b may be set to the same potential as one of the potentials at the busbars of the first IDT electrode 12 and the second IDT electrode 13. Nonetheless, each of the reflectors may be a floating electrode. The floating electrode means an electrode connected to neither the signal electrode nor to the ground electrode.

An example of a preferable structure of an example embodiment of the present invention will be shown below.

The impedance ratio of the third harmonic wave was calculated every time the second Euler angle θ1 of the first lithium niobate layer 7 was changed. In this instance, the second Euler angle θ2 of the second lithium niobate layer 8 was set to about θ1+180°. The design parameters of the acoustic wave device concerning this investigation are as follows:
Support substrate: material . . . Si, plane orientation . . . (111), third Euler angle ψ_{Si} . . . about 73°;
First layer of intermediate layer: material . . . SiN, thickness . . . about 300 nm;
Second layer of intermediate layer: material . . . SiO₂, thickness . . . about 200 nm;
First lithium niobate layer: material . . . rotated Y-cut LiNbO₃, first Euler angle φ1 . . . about 0°, second Euler angle θ1 . . . changed in increments of about 5° in a range from equal to or greater than about −90° to equal to or below about 90°, third Euler angle ψ1 . . . about 0°, thickness . . . about 250 nm;
Second lithium niobate layer: material . . . rotated Y-cut LiNbO₃, first Euler angle ψ2 . . . about 0°, second Euler angle θ2, about θ1+180°, third Euler angle ψ2 . . . about 0°, thickness . . . about 250 nm;
First IDT electrode: layer structure . . . Ti layer/Al layer from first lithium niobate layer side, thickness . . . about 12 nm/about 70 nm from first lithium niobate layer side, wavelength λ1 . . . about 2.7 μm, duty ratio . . . about 0.8; and
Second IDT electrode: layer structure . . . Ti layer/Al layer from second lithium niobate layer side, thickness . . . about 12 nm/about 70 nm from second lithium niobate layer side, wavelength λ2 . . . about 2.7 μm, duty ratio . . . about 0.8.

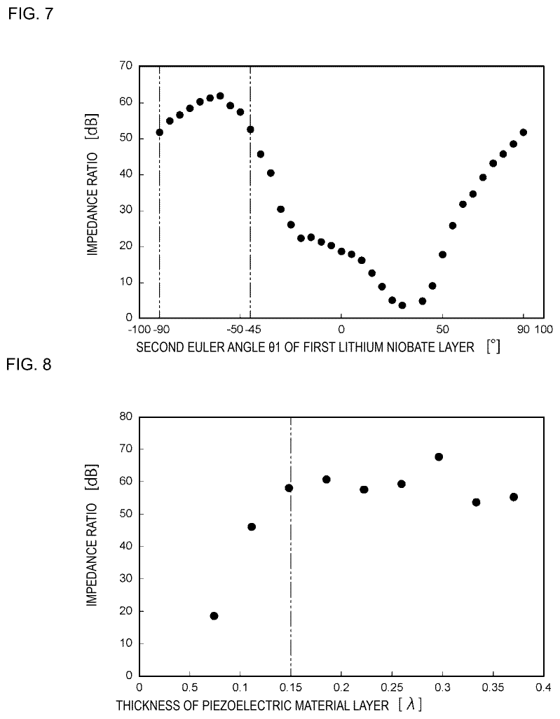

FIG. 7 is a diagram showing a relationship between the second Euler angle θ1 of the first lithium niobate layer and the impedance ratio of the third harmonic wave.

As shown in FIG. 7, the impedance ratio of the third harmonic wave is particularly high in a case where the second Euler angle θ1 of the first lithium niobate layer 7 satisfies about −90°≤θ1≤about −45°. Here, it has been known that an influence on the impedance frequency characteristics is not changed in rotated Y-cut lithium niobate in a case where the second Euler angle θ is different by about 180°. From this aspect, for example, assuming that n is a natural number, the second Euler angle θ1 of the first lithium niobate layer 7 preferably satisfies −90°+180°×n≤θ1≤−45°+180°×n. Thus, the impedance ratio of the third harmonic wave can be increased effectively.

Here, it has been known that an influence on the impedance frequency characteristics of lithium niobate is not changed in a case where the first Euler angle φ is in a range within about 0°±5° and the third Euler angle ψ is in a range within about 0°±5°. From this aspect, for example, the Euler angles (φ1, θ1, ψ1) of the first lithium niobate layer 7 preferably satisfy (the range within 0°±5°, −90°+180°×n≤θ1≤−45+180°×n, the range within 0°±5°). In this case, the Euler angles (φ2, θ2, ψ2) of the second lithium niobate layer 8 preferably satisfy (the range within 0°±5°, a range within θ1±180°×m±5, the range within 0°±5°). Here, the value m is assumed to be an odd number such as m=1, 3, 5, and so on. Thus, the impedance ratio of the third harmonic wave can be increased effectively.

In the following description, of the wavelength λ1 defined by the electrode finger pitch of the first IDT electrode 12 and the wavelength λ2 defined by the electrode finger pitch of the second IDT electrode 13, one that is not larger is assumed to be a wavelength λ. More specifically, the wavelength λ is equal to λ2 in the case where λ1>λ2 holds true. The wavelength λ is equal to λ1 in the case where λ1<λ2 holds true. The wavelength λ is equal to λ1 and λ2 in the case where λ1=λ2 holds true.

A thickness of the piezoelectric layer 6 is, for example, preferably equal to or below about 1λ. Thus, it is possible to improve excitation efficiency of the third harmonic wave. That is to say, a total thickness of the first lithium niobate layer 7 and the second lithium niobate layer 8 is, for example, preferably equal to or below about 1λ. The thickness of the piezoelectric layer 6 is not limited to the above description.

In addition, the impedance ratio of the third harmonic wave was calculated every time the thickness of the piezoelectric layer 6 was changed. Here, the thicknesses of the first lithium niobate layer 7 and the second lithium niobate layer 8 were set equal. Moreover, λ=λ1=λ2 is satisfied. For this reason, the thickness of the piezoelectric layer 6 will be indicated based on the wavelength λ in this investigation. The design parameters of the acoustic wave device 1 is this investigation are the same or substantially the same as the design parameters of the acoustic wave device 1 that derived the relation shown in FIG. 7, except for the piezoelectric layer 6:

Piezoelectric layer: thickness . . . changed in increments of about 100 nm in a range from equal to or greater than about 200 nm to equal to or below about 1000 nm and changed in increments of about 0.037λ in a range from equal to or greater than about 0.074λ to equal to or below about 0.37λ based on the wavelength λ;

First lithium niobate layer: material . . . rotated Y-cut LiNbO₃, Euler angles (φ1, θ1, ψ1) . . . (0°, 120°, 0°), thickness . . . changed in increments of about 50 nm in a range from equal to or greater than about 100 nm to equal to or below about 500 nm; and

Second lithium niobate layer: material . . . rotated Y-cut LiNbO₃, Euler angles (φ2, θ2, ψ2) . . . (0°, −60°, 0°), thickness . . . changed in increments of about 50 nm in the range from equal to or greater than about 100 nm to equal to or below about 500 nm.

FIG. 8 is a diagram showing a relation between the thickness of the piezoelectric layer and the impedance ratio of the third harmonic wave.

As shown in FIG. 8, the impedance ratio of the third harmonic wave is particularly high in a case where the thickness of the piezoelectric layer 6 is equal to or greater than about 0.15λ. From this aspect, the thickness of the piezoelectric layer 6 is, for example, preferably equal to or greater than about 0.15λ based on the wavelength λ that is not the larger one of the wavelength λ1 defined by the electrode finger pitch of the first IDT electrode 12 and the wavelength λ2 defined by the electrode finger pitch of the second IDT electrode 13. That is to say, the total thickness of the first lithium niobate layer 7 and the second lithium niobate layer 8 is, for example, preferably equal to or greater than about 0.15λ. Thus, the impedance ratio of the third harmonic wave can be increased effectively.

In the first example embodiment, of the first lithium niobate layer 7 and the second lithium niobate layer 8, the first lithium niobate layer 7 is located on the support substrate 2 side. The thickness of the first lithium niobate layer 7 is preferably larger than the thickness of the second lithium niobate layer 8. Thus, it is possible to reduce or prevent a second harmonic wave. Here, the second harmonic wave becomes an unnecessary wave in the case of using the third harmonic wave to operate the acoustic wave device 1. Details of this advantageous effect will be shown below.

The impedance frequency characteristics were evaluated every time the thicknesses of the first lithium niobate layer 7 and the second lithium niobate layer 8 were changed. Here, the thickness of the piezoelectric layer 6 as the total of the thicknesses of the first lithium niobate layer 7 and the second lithium niobate layer 8 was set constant. Specifically, for example, the thickness of the piezoelectric layer 6 was set to about 500 nm. The design parameters of the acoustic wave device 1 in this investigation are the same or substantially the same as the design parameters of the acoustic wave device 1 with the relationship shown in FIG. 7 except for the piezoelectric layer 6. In the following description, a value obtained by dividing the thickness of the first lithium niobate layer 7 by the thickness of the second lithium niobate layer 8 is assumed to be a thickness ratio between the first lithium niobate layer 7 and the second lithium niobate layer 8:

Piezoelectric layer: thickness . . . 500 nm, thickness ratio between first lithium niobate layer and second lithium niobate layer . . . about 2.33, about 1.5, about 1, about 0.67, about 0.43, or about 0.25;

First lithium niobate layer: material . . . rotated Y-cut LiNbO₃, Euler angles (φ1, θ1, ψ1) . . . (0°, 120°, 0°), thickness . . . changed in increments of about 50 nm in a range from equal to or greater than about 100 nm to equal to or below about 350 nm; and

Second lithium niobate layer: material . . . rotated Y-cut LiNbO₃, Euler angles (φ2, θ2, ψ2) . . . (0°, −60°, 0°), thickness . . . changed in increments of about 50 nm in a range from equal to or greater than about 150 nm to equal to or below about 400 nm.

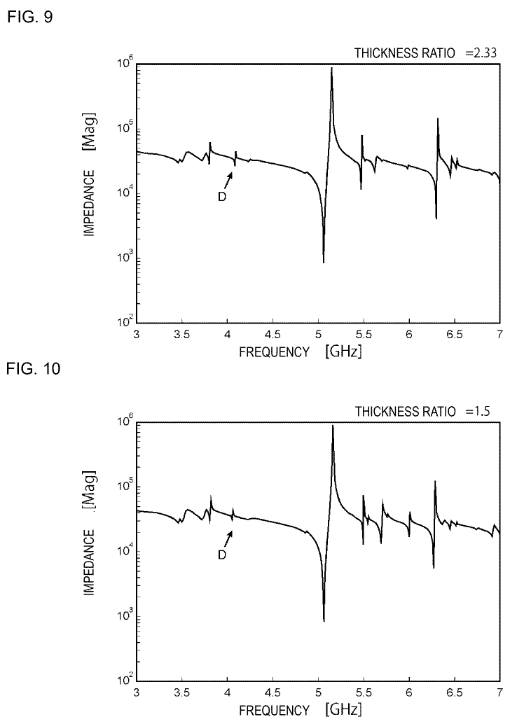

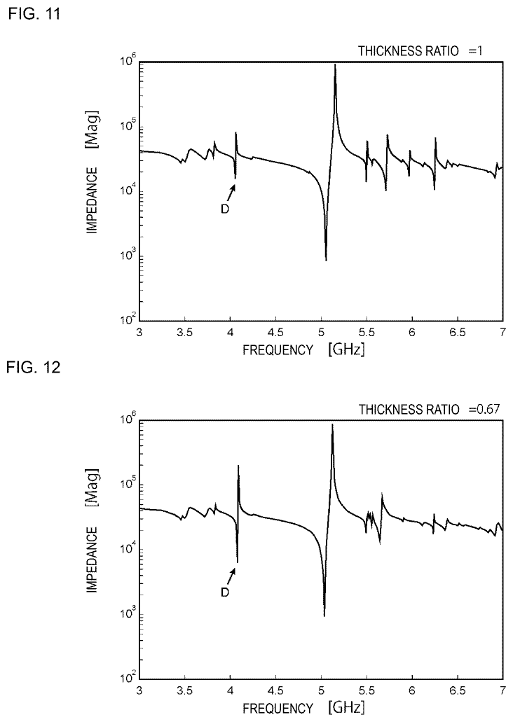

FIG. 9 is a diagram showing the impedance frequency characteristics in a case where the thickness ratio between the first lithium niobate layer and the second lithium niobate layer is about 2.33. FIG. 10 is a diagram showing the impedance frequency characteristics in a case where the thickness ratio between the first lithium niobate layer and the second lithium niobate layer is about 1.5. FIG. 11 is a diagram showing the impedance frequency characteristics in a case where the thickness ratio between the first lithium niobate layer and the second lithium niobate layer is about 1. An arrow D in FIGS. 9 to 11 indicates a ripple attributed to the second harmonic wave. The same applies to the drawings illustrating the impedance frequency characteristics other than FIGS. 9 to 11.

As shown in FIGS. 9 to 11, the second harmonic wave is reduced or prevented in the case where the thickness ratio between the first lithium niobate layer 7 and the second lithium niobate layer 8 is equal to or greater than about 1 and the thickness of the first lithium niobate layer 7 is equal to or larger than the thickness of the second lithium niobate layer 8. In addition, as shown in FIGS. 9 and 10, the second harmonic wave is effectively reduced or prevented in the case where the value of the thickness ratio between the first lithium niobate layer 7 and the second lithium niobate layer 8 is larger than about 1 and the thickness of the first lithium niobate layer 7 is larger than the thickness of the second lithium niobate layer 8. This is because an influence of the layers other than the piezoelectric layer 6 on the electric characteristics of the acoustic wave device 1 can be reduced or prevented since the thickness of the first lithium niobate layer 7 located on the support substrate 2 side is large.

On the other hand, results in the case where the thickness of the first lithium niobate layer 7 is smaller than the thickness of the second lithium niobate layer 8 are shown in FIGS. 12 to 14.

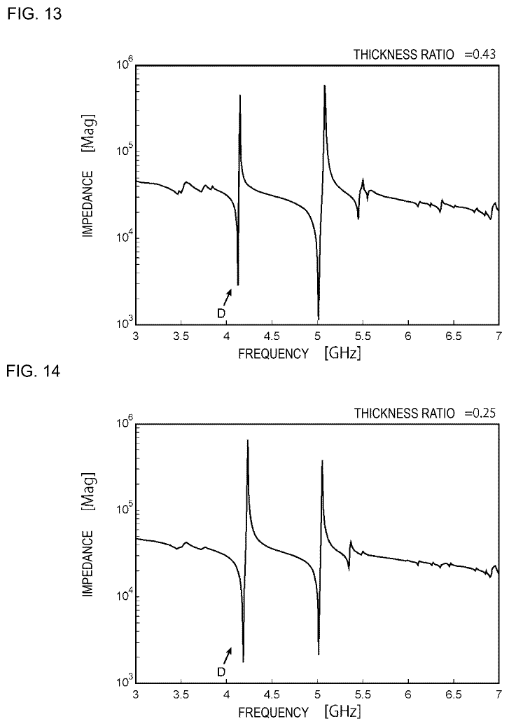

FIG. 12 is a diagram showing the impedance frequency characteristics in a case where the thickness ratio between the first lithium niobate layer and the second lithium niobate layer is about 0.67. FIG. 13 is a diagram showing the impedance frequency characteristics in a case where the thickness ratio between the first lithium niobate layer and the second lithium niobate layer is about 0.43. FIG. 14 is a diagram showing the impedance frequency characteristics in a case where the thickness ratio between the first lithium niobate layer and the second lithium niobate layer is about 0.25.

As shown in FIGS. 12 to 14, an impedance ratio of the second harmonic wave is large in the case where the thickness ratio between the first lithium niobate layer 7 and the second lithium niobate layer 8 is below about 1 and the thickness of the first lithium niobate layer 7 is smaller than the thickness of the second lithium niobate layer 8. The impedance ratio of the second harmonic wave is larger as the thickness ratio between the first lithium niobate layer 7 and the second lithium niobate layer 8 is smaller.

Here, the fundamental wave is generated at a frequency on a lower side from the ranges shown in FIGS. 9 to 14. However, the fundamental wave is reduced or prevented in any case of the thickness ratios between the first lithium niobate layer 7 and the second lithium niobate layer 8.

The impedance ratio of the third harmonic wave was calculated every time the thicknesses of the first IDT electrode 12 and the second IDT electrode 13 were changed. To be more precise, a structure of laminating a close contact layer and a main electrode layer was provided as a layer structure of the first IDT electrode 12 and of the second IDT electrode 13. The close contact layer is a layer that comes into close contact with a piezoelectric substrate in the IDT electrode. The main electrode layer is a layer that exceeds about 50% by weight in the layer structure of the IDT electrode. For example, in a case where the IDT electrode includes a single layer, the IDT electrode includes the main electrode layer. That is to say, each of the first IDT electrode 12 and the second IDT electrode 13 includes at least the main electrode layer. In this investigation, the close contact layer is the Ti layer and the main electrode layer is the Al layer. The thickness of the first IDT electrode 12 was set equal to the thickness of the second IDT electrode 13. The design parameters of the acoustic wave device 1 in this investigation are as follows:
Support substrate: material . . . Si, plane orientation (111), third Euler angle ψ_{Si} . . . about 73°;
First layer of intermediate layer: material . . . SiN, thickness . . . about 300 nm;
Second layer of intermediate layer: material . . . SiO₂, thickness . . . about 200 nm;
First lithium niobate layer: material . . . rotated Y-cut LiNbO₃, Euler angles (φ1, θ1, ψ1) . . . (0°, 120°, 0°), thickness . . . about 250 nm;
Second lithium niobate layer: material . . . rotated Y-cut LiNbO₃, Euler angles (φ2, θ2, ψ2) . . . (0°, −60°, 0°), thickness . . . about 250 nm.

First IDT electrode: layer structure . . . Ti layer/Al layer from first lithium niobate layer side, thickness . . . about 12 nm/changed in increments of about 10 nm in a range from equal to or greater than about 10 nm to equal to or below about 190 nm from first lithium niobate layer side, wavelength λ1 . . . about 2.7 μm, duty ratio . . . about 0.8; and

Second IDT electrode: layer structure . . . Ti layer/Al layer from second lithium niobate layer side, thickness . . . about 12 nm/changed in increments of 10 nm in the range from equal to or greater than about 10 nm to equal to or below about 190 nm from second lithium niobate layer side, wavelength λ2 . . . about 2.7 μm, duty ratio . . . about 0.8.

In this investigation, the wavelength λ1 defined by the electrode finger pitch of the first IDT electrode 12 and the wavelength λ2 defined by the electrode finger pitch of the second IDT electrode 13 were set equal. That is to say, λ1=λ2=λ is satisfied. For this reason, in this investigation, the thicknesses of the first IDT electrode 12 and the second IDT electrode 13 will be indicated based on the wavelength λ. The thickness of the main electrode layer in the first IDT electrode 12 and the thickness of the main electrode layer in the second IDT electrode 13 were changed in increments of about 0.0037λ in a range from equal to or greater than about 0.0037λ to equal to or below about 0.07λ.

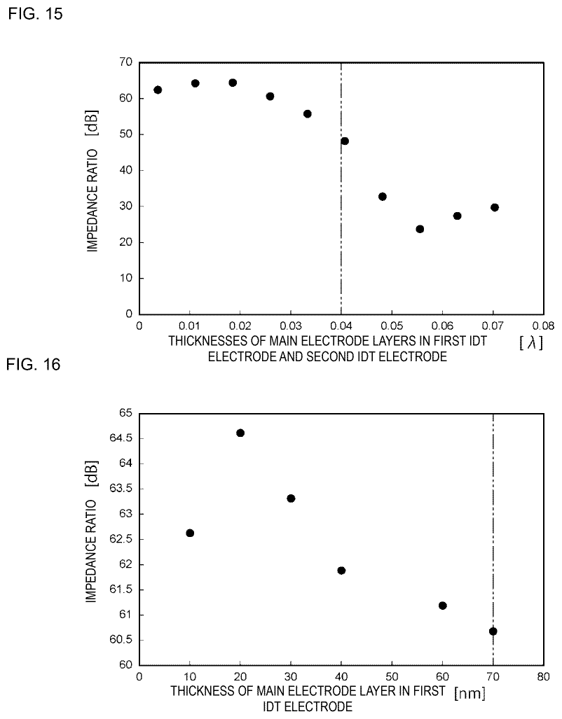

FIG. 15 is a diagram showing a relationship between the thickness of the main electrode layer in each of the first IDT electrode and the second IDT electrode, and the impedance ratio of the third harmonic wave.

As shown in FIG. 15, it was discovered that the impedance ratio of the third harmonic wave becomes large in a case where the thickness of the main electrode layer in each of the first IDT electrode 12 and the second IDT electrode 13 is equal to or below about 0.04λ. From this aspect, the thickness of the main electrode layer in each of the first IDT electrode 12 and the second IDT electrode 13 is, for example, preferably equal to or below about 0.04λ. More specifically, the thickness of the main electrode layer in the first IDT electrode 12 is, for example, preferably equal to or below about 0.04λ1, and the thickness of the main electrode layer in the second IDT electrode 13 is, for example, preferably equal to or below about 0.04λ2. Thus, the impedance ratio of the third harmonic wave can be increased.

Here, the material of the main electrode layers of the first IDT electrode 12 and the second IDT electrode 13 is not limited to Al. For example, even in a case where the λ1=λ2=λ is satisfied and the material of the respective main electrode layers is other than Al, it is possible to obtain the advantageous effect of increasing the impedance ratio of the third harmonic wave as long as a density-converted thickness based on a density of Al is equal to or below about 0.04λ. This is attributed to the fact that mass addition to the piezoelectric layer 6 is equal irrespective of the materials of the respective main electrode layers as long the as above-described density-converted thicknesses in the respective main electrode layers are equal.

More specifically, when the density of Al is assumed to be ρ_{A1}, the density of the material of the main electrode layer is assumed to be ρ_{M}, the thickness of the main electrode layer is assumed to be t_{M}, and the density-converted thickness of the main electrode layer based on the density of Al is assumed to be t_{C}, the density-converted thickness to is expressed by t_{C}=(ρ_{M}/ρ_{A1})×t_{M}. The density-converted thickness t_{C} of the main electrode layer in the first IDT electrode 12 is, for example, preferably equal to or below about 0.04λ1, and the density-converted thickness t_{C} of the main electrode layer in the second IDT electrode 13 is, for example, preferably equal to or below about 0.04λ2. Thus, the impedance ratio of the third harmonic wave can be increased.

In the first example embodiment, of the first IDT electrode 12 and the second IDT electrode 13, the first IDT electrode 12 is located on the support substrate 2 side. In this case, the thickness of the first IDT electrode 12 is preferably smaller than the thickness of the second IDT electrode 13. Thus, it is possible to reduce or prevent a leakage of the acoustic wave to the support substrate 2 side, and to confine the acoustic wave on the piezoelectric layer 6 side. Accordingly, a Q factor of the acoustic wave device 1 can be improved. Thus, the impedance ratio of the third harmonic wave can be increased. Details of this advantageous effect will be shown below.

The impedance ratio of the third harmonic wave was calculated every time the thickness of the first IDT electrode 12 was changed. The design parameters of the acoustic wave device 1 is this investigation are the same or substantially the same as the design parameters of the acoustic wave device 1 that derived the relation shown in FIG. 5 except for the first IDT electrode 12 and the second IDT electrode 13:

First IDT electrode: layer structure . . . Ti layer/Al layer from first lithium niobate layer side, thickness . . . about 12 nm/changed in increments of about 10 nm in a range from equal to or greater than about 10 nm to equal to or below about 70 nm from first lithium niobate layer side, wavelength λ1 . . . about 2.7 μm, duty ratio . . . about 0.8; and

Second IDT electrode: layer structure . . . Ti layer/Al layer from second lithium niobate layer side, thickness . . . about 12 nm/about 70 nm from second lithium niobate layer side, wavelength λ2 . . . about 2.7 μm, duty ratio . . . about 0.8.

FIG. 16 is a diagram showing a relationship between the thickness of the main electrode layer in the first IDT electrode and the impedance ratio of the third harmonic wave. In FIG. 16, when the thickness of the main electrode layer in the first IDT electrode 12 is about 70 nm, the thickness of this main electrode layer is equal to the thickness of the main electrode layer in the second IDT electrode 13.

As shown in FIG. 16, it was discovered that the impedance ratio of the third harmonic wave becomes large in a case where the thickness of the main electrode layer in the first IDT electrode 12 is smaller than about 70 nm. That is to say, the impedance ratio of the third harmonic wave is large in the case where the thickness of the main electrode layer in the first IDT electrode 12 is smaller than the thickness of the main electrode layer in the second IDT electrode 13. Here, the thicknesses of the close contact layers in the first IDT electrode 12 and the second IDT electrode 13 are equal. Accordingly, the impedance ratio of the third harmonic wave can be increased in the case where the thickness of the first IDT electrode 12 is smaller than the thickness of the second IDT electrode 13.

The density of the material used in the first IDT electrode 12 is preferably higher than the density of the material used in the second IDT electrode 13. Thus, it is possible to reduce or prevent a leakage of the acoustic wave to the support substrate 2, and to confine the acoustic wave in the piezoelectric layer 6. Accordingly, the Q factor of the acoustic wave device 1 can be improved. Thus, the impedance ratio of the third harmonic wave can be increased. In addition, it is possible to reduce or prevent the second harmonic wave. Details of this advantageous effect will be shown below.

The impedance frequency characteristics were compared while changing the densities of the materials of the main electrode layers in the first IDT electrodes 12. In one of the acoustic wave devices 1, Al was used as the material of the main electrode layer in the first IDT electrode 12. In another one of the acoustic wave devices 1, Pt was used as the material of the main electrode layer in the first IDT electrode 12. The design parameters of each of the acoustic wave devices 1 in this investigation were the same or substantially the same as the design parameters of the acoustic wave device 1 with the relationship shown in FIG. 5 except for the first IDT electrode 12 and the second IDT electrode 13. The design parameters of the one acoustic wave device 1 are as follows:

First IDT electrode: layer structure . . . Ti layer/Al layer from first lithium niobate layer side, thickness . . . about 12 nm/about 70 nm from first lithium niobate layer side, wavelength λ1 . . . about 2.7 μm, duty ratio . . . about 0.8; and

Second IDT electrode: layer structure . . . Ti layer/Al layer from second lithium niobate layer side, thickness . . . about 12 nm/about 70 nm from second lithium niobate layer side, wavelength λ2 . . . about 2.7 μm, duty ratio . . . about 0.8.

The design parameters of the other acoustic wave device 1 are as follows:

First IDT electrode: layer structure . . . Ti layer/Pt layer from first lithium niobate layer side, thickness . . . about 12 nm/about 10 nm from first lithium niobate layer side, wavelength λ1 . . . about 2.7 μm, duty ratio . . . about 0.8; and

Second IDT electrode: layer structure . . . Ti layer/Al layer from second lithium niobate layer side, thickness . . . about 12 nm/about 70 nm from second lithium niobate layer side, wavelength λ2 . . . about 2.7 μm, duty ratio . . . about 0.8.

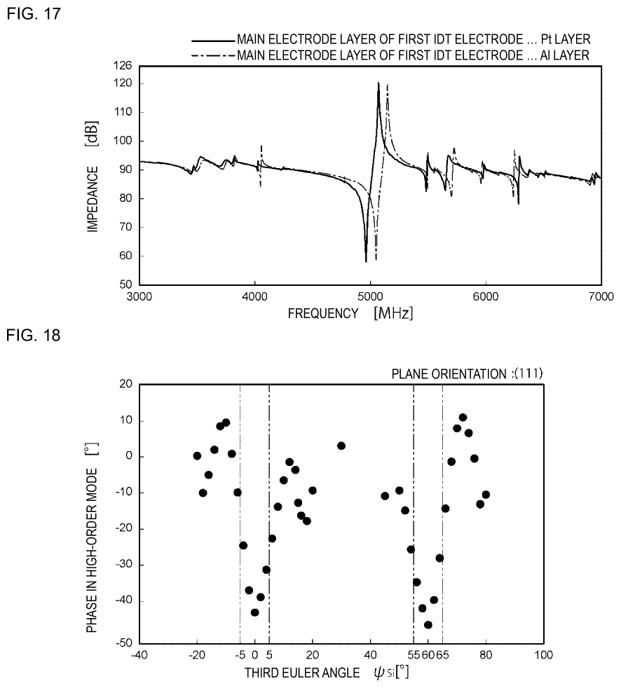

FIG. 17 is a diagram showing the impedance frequency characteristics in the case where the main electrode layer in the first IDT electrode is the Pt layer and in the case where this layer is the Al layer.

As shown in FIG. 17, in the case where the main electrode layer in the first IDT electrode 12 is the Pt layer, it was discovered that the impedance ratio is larger than that in the case where the main electrode layer in the first IDT electrode 12 is the Al layer. In addition, in the case where the main electrode layer in the first IDT electrode 12 is the Pt layer, it was discovered that an unnecessary wave in the vicinity of about 4000 MHz is reduced or prevented more as compared to the case where the main electrode layer in the first IDT electrode 12 is the Al layer. Here, the combination of the materials of the main electrode layer in the first IDT electrode 12 and of the main electrode layer in the second IDT electrode 13 is not limited to the set of Al and Al or the set of Pt and Al.

Here, a relationship between the Euler angles of the support substrate 2 being the silicon substrate and a high-order mode being an unnecessary wave was evaluated. Specifically, the high-order mode stated herein is a high-order mode generated in the vicinity of a range from about 5300 MHz to about 6100 MHz. More specifically, a phase of the high-order mode was evaluated every time the third Euler angle ψ_{Si} of the support substrate 2 was changed while setting the plane orientation thereof to (111). The design parameters of the acoustic wave device 1 in this investigation are as follows:
Support substrate: material . . . Si, plane orientation . . . (111), third Euler angle ψ_{Si} . . . changed in increments of about 2° in a range from equal to or greater than about −20° to equal to or below about 20°, then changed in increments of about 10° in a range from equal to or greater than about 20° to equal to or below about 40°, and then changed in increments of about 2° in a range from equal to or greater than about 40° to equal to or below about 80°;
First layer of intermediate layer: material . . . SiN, thickness . . . about 300 nm;
Second layer of intermediate layer: material . . . SiO₂, thickness . . . about 200 nm;
First lithium niobate layer: material . . . rotated Y-cut LiNbO₃, Euler angles (φ1, θ1, ψ1) . . . (0°, 120°, 0°), thickness . . . about 250 nm;
Second lithium niobate layer: material . . . rotated Y-cut LiNbO₃, Euler angles (φ2, θ2, ψ2) . . . (0°, −60°, 0°), thickness . . . about 250 nm;
First IDT electrode: layer structure . . . Ti layer/Al layer from first lithium niobate layer side, thickness . . . about 12 nm/about 70 nm from first lithium niobate layer side, wavelength λ1 . . . about 2.7 μm, duty ratio . . . about 0.8; and
Second IDT electrode: layer structure . . . Ti layer/Al layer from second lithium niobate layer side, thickness . . . about 12 nm/about 70 nm from second lithium niobate layer side, wavelength λ2 . . . about 2.7 μm, duty ratio . . . about 0.8.

FIG. 18 is a diagram showing a relationship between the third Euler angle of the support substrate and a phase in the high-order mode in the case where the plane orientation of the support substrate is (111).

As shown in FIG. 18, it was discovered that the high-order mode is reduced or prevented particularly in a case where the third Euler angle ψ_{Si} of the support substrate 2 is in a range within about 0°±5° and in a case where this angle is in a range within about 60°±5°.

The plane orientation being (111) means an act of cutting in a crystal structure of silicon having a diamond structure along the (111) plane orthogonal or substantially orthogonal to a crystal axis expressed by the Miller indices [111]. The piezoelectric layer 6 shown in FIG. 1 is provided on this (111) plane. More specifically, the piezoelectric layer 6 is provided on the (111) plane of the support substrate 2 with the intermediate layer 3 interposed therebetween. The (111) plane has a crystal structure having in-plane three-fold symmetry, and a crystal structure rotated by about 120° is equivalent thereto.

As described above, when n is assumed to be a natural number and the plane orientation of the support substrate 2 is (111), the third Euler angle ψ_{Si} of the support substrate 2 preferably satisfies the following. Specifically, the third Euler angle ψ_{Si} is preferably in any of a range within about (0°+120°×n)±5° and a range within about (60°+120°×n)±5°. Thus, the high-order mode can be reduced or prevented. In this case, it is possible to reduce or prevent deterioration of filter characteristics in the filter device in the case where the acoustic wave device 1 is used as the filter device.

In addition, the plane orientation of the support substrate 2 was set to (110) and the phase of the high-order mode was evaluated every time the third Euler angle ψ_{Si} was changed. The high-order mode stated herein is the high-order mode generated in the vicinity of the range from about 5300 MHz to about 6100 MHz. The design parameters of the acoustic wave device 1 in this investigation are the same or substantially the same as those of the acoustic wave device 1 obtained the relation in FIG. 18 except for the support substrate 2:

Support substrate: material . . . Si, plane orientation . . . (110), third Euler angle ψ_{Si} . . . changed in increments of about 2° in a range from equal to or greater than about 0° to equal to or below about 360°.

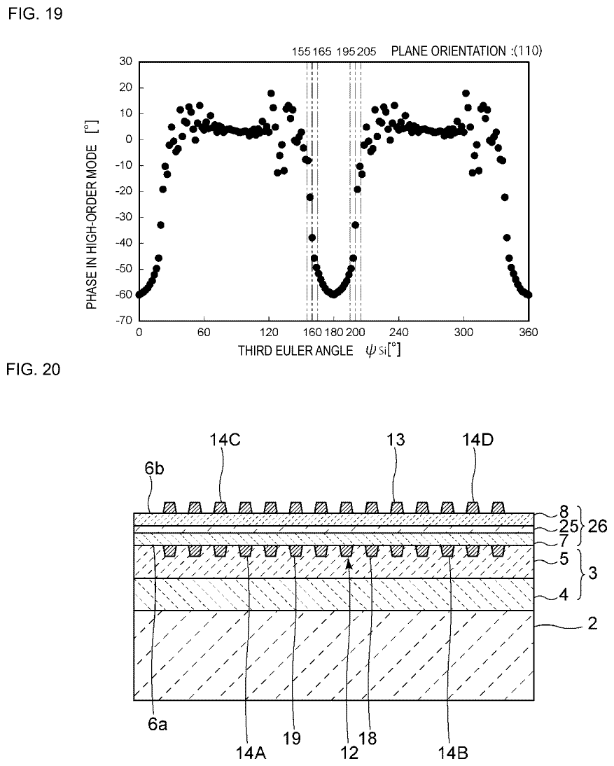

FIG. 19 is a diagram showing the relationship between the third Euler angle of the support substrate and the phase in the high-order mode in the case where the plane orientation of the support substrate is (110).

As shown in FIG. 19, the high-order mode is reduced or prevented particularly in a case where the third Euler angle ψ_{Si} of the support substrate 2 is in a range from equal to or greater than about 155° to equal or below about 205°. The high-order mode is reduced or prevented effectively in a case where the third Euler angle ψ_{Si} is in a range from equal to or greater than about 160° to equal to or below about 200°. The high-order mode is reduced or prevented further in a case where the third Euler angle ψ_{Si} is in a range from equal to or greater than about 165° to equal or below about 195°.

The plane orientation being (110) means an act of cutting in the crystal structure of silicon having the diamond structure along the (110) plane orthogonal or substantially orthogonal to a crystal axis expressed by the Miller indices. The piezoelectric layer 6 shown in FIG. 1 is provided on this (110) plane. More specifically, the piezoelectric layer 6 is provided indirectly on the (110) plane of the support substrate 2 with the intermediate layer 3 interposed therebetween. The (110) plane has in-plane two-fold symmetry, and a crystal structure rotated by about 180° is equivalent thereto.

As described above, when n is assumed to be a natural number and the plane orientation of the support substrate 2 is (110), the third Euler angle ψ_{Si} of the support substrate 2 preferably satisfies the following. Specifically, the third Euler angle ψ_{Si} is, for example, preferably equal to or greater than about 155°+180°×n and equal to or below about 205°+180°×n. The third Euler angle ψ_{Si} is, for example, more preferably equal to or greater than about 160°+180°×n and equal to or below about 200°+180°×n, or even more preferably equal to or greater than about 165°+180°×n and equal to or below about 195°+180°×n. Thus, the high-order mode can be reduced or prevented. In this case, it is possible to reduce or prevent deterioration of filter characteristics in the filter device in the case where the acoustic wave device 1 is used as the filter device.

The second principal surface 6b of the piezoelectric layer 6 shown in FIG. 1 may be provided with a dielectric film so as to cover the second IDT electrode 13. In this case, the second IDT electrode 13 is protected by the dielectric film and is less likely to be damaged. For example, silicon oxide, silicon nitride, silicon oxynitride, or the like can be used as a material of the dielectric film. The structure provided with this dielectric film is not limited only to the first example embodiment but can also be used with structures of the present invention other than the first example embodiment.

In the first example embodiment, the second lithium niobate layer 8 is directly laminated on the first lithium niobate layer 7. Here, the second lithium niobate layer 8 may be indirectly laminated on the first lithium niobate layer 7 with another layer interposed therebetween. This example will be described as a second example embodiment of the present invention.

FIG. 20 is a schematic elevational sectional view of an acoustic wave device according to a second example embodiment of the present invention.

The present example embodiment is different from the first example embodiment in that a dielectric layer 25 is provided between the first lithium niobate layer 7 and the second lithium niobate layer 8. Except for the above-described aspect, the acoustic wave device of the present example embodiment has the same or substantially the same structure as that of the acoustic wave device 1 of the first example embodiment.

A piezoelectric layer 26 includes the first lithium niobate layer 7, the second lithium niobate layer 8, and the dielectric layer 25. For example, silicon oxide or the like can be used as a material of the dielectric layer 25.

In the present example embodiment as well, the directions of polarization of the first lithium niobate layer 7 and the second lithium niobate layer 8 are inverted to each other in the thickness direction of the piezoelectric layer 26 as with the first example embodiment. The duty ratio of each of the first IDT electrode 12 and the second IDT electrode 13 is equal to or greater than about 0.6, for example. Thus, the third harmonic wave can be strongly excited and the fundamental wave as the unnecessary wave can be reduced or prevented.

A thickness of the piezoelectric layer 26 is, for example, preferably equal to or below about 1λ. Thus, it is possible to improve excitation efficiency of the third harmonic wave. Here, as described above, the wavelength λ is the one that is not larger out of the wavelength λ1 defined by the electrode finger pitch of the first IDT electrode 12 and the wavelength λ2 defined by the electrode finger pitch of the second IDT electrode 13.

A thickness of the dielectric layer 25 is preferably smaller than the thickness of the first lithium niobate layer 7 and the thickness of the second lithium niobate layer 8. In this case, the third harmonic wave can be excited even more reliably and strongly.

In the present example embodiment as well, the total thickness of the first lithium niobate layer 7 and the second lithium niobate layer 8 is, for example, preferably equal to or greater than about 0.15λ from the relationship shown in FIG. 8. Thus, the impedance ratio of the third harmonic wave can be increased effectively.

A structure in which the first IDT electrode 12 is electrically connected to the second IDT electrode 13 is not shown in FIG. 1 and the like. Nonetheless, the busbars of the first IDT electrode 12 and the second IDT electrode 13 may be connected to each other by a through electrode and the like, for example. The through electrode means an electrode that penetrates the piezoelectric layer 6. Similarly, the busbars of the first IDT electrode 12 and the second IDT electrode 13 may be connected to each other by using a through electrode and the like in the second example embodiment as well.

An example of the structure in which the first IDT electrode is electrically connected to the second IDT electrode will be shown below.

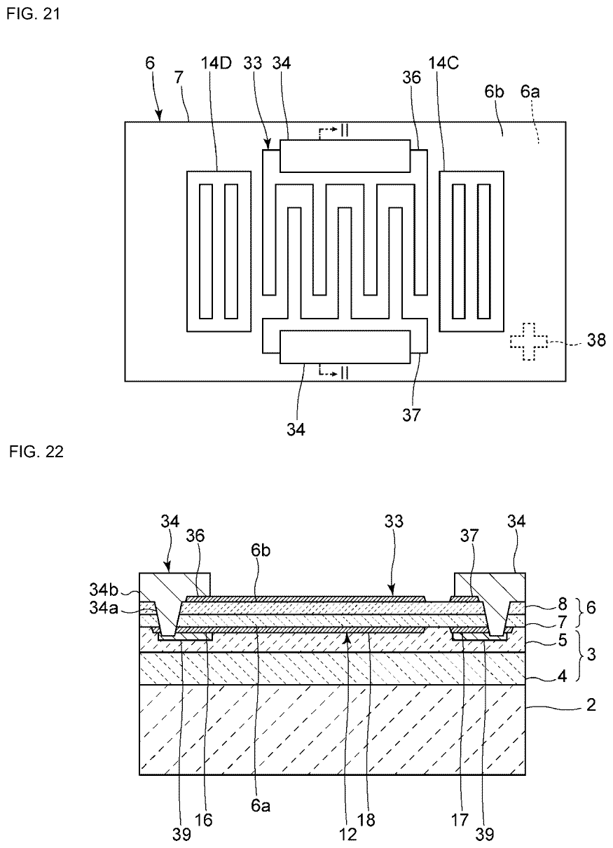

FIG. 21 is a schematic plan view of an acoustic wave device according to a third example embodiment of the present invention. FIG. 22 is a schematic sectional view taken along line II-II in FIG. 21. Here, FIG. 2 is a schematic bottom view and FIG. 21 is the schematic plan view. For this reason, FIG. 21 is horizontally flipped relative to the diagram viewed from the bottom such as FIG. 2.

As shown in FIG. 21, the present example embodiment is different from the first example embodiment in that a pair of conducting portions 34 are provided. The present example embodiment is also different from the first example embodiment in that the first principal surface 6a of the piezoelectric layer 6 includes an alignment mark 38. As shown in FIG. 22, the present example embodiment is also different from the first example embodiment in that a pair of stopping layers 39 are provided. Except for the above-described aspects, the acoustic wave device of the present example embodiment has the same or substantially the same structure as that of the acoustic wave device 1 of the first example embodiment.

A second IDT electrode 33 shown in FIG. 21 is provided in the same way as the second IDT electrode 13 in the first example embodiment. Here, a pair of busbars of the second IDT electrode 33 are specifically a third busbar 36 and a fourth busbar 37. The third busbar 36 and the fourth busbar 37 are opposed to each other. One conducting portion 34 of the pair of conducting portions 34 is connected to the third busbar 36. Another one conducting portion 34 of the pair of conducting portions 34 is connected to the fourth busbar 37.

As shown in FIG. 22, the one conducting portion 34 of the pair of conducting portions 34 connects the first busbar 16 in the first IDT electrode 12 and the third busbar 36 in the second IDT electrode 33. The other conducting portion 34 connects the second busbar 17 in the first IDT electrode 12 and the fourth busbar 37 in the second IDT electrode 33.

Specifically, the conducting portion 34 includes a through electrode 34a and a busbar connection electrode 34b. The through electrode 34a penetrates the piezoelectric layer 6. The busbar connection electrode 34b connects the through electrode 34a and the busbar of the second IDT electrode 33. More specifically, the busbar connection electrode 34b at the one conducting portion 34 of the pair of conducting portions 34 is provided across a portion on the third busbar 36 and a portion on the second principal surface 6b of the piezoelectric layer 6, and is connected to the through electrode 34a.

The busbar connection electrode 34b at the other conducting portion 34 is provided across a portion on the fourth busbar 37 and a portion on the second principal surface 6b of the piezoelectric layer 6, and is connected to the through electrode 34a. Nonetheless, the through electrode 34a and the busbar connection electrode 34b of the conducting portion 34 are integrally provided using the same material. Here, the through electrode 34a and the busbar connection electrode 34b of the conducting portion 34 may include different materials from each other.

The stopping layer 39 is provided on the first busbar 16 of the first IDT electrode 12. More specifically, the first busbar 16 and the stopping layer 39 are laminated in this order from the piezoelectric layer 6 side. Similarly, the stopping layer 39 is provided on the second busbar 17. The second busbar 17 and the stopping layer 39 are laminated in this order from the piezoelectric layer 6 side.

The stopping layers 39 are layers to reduce or prevent etching of the intermediate layer 3 and the support substrate 2 at the time of etching the busbars of the first IDT electrode 12 when the acoustic wave device is manufactured. An etching rate of the stopping layers 39 is equal to or below an etching rate of the first IDT electrode 12.

The through electrode 34a of the one conducting portion 34 of the pair of conducting portions 34 penetrates the piezoelectric layer 6 and the first busbar 16 of the first IDT electrode 12, and is connected to the stopping layer 39. To be more precise, the piezoelectric layer 6 and the first busbar 16 are provided with a through hole, and the stopping layer 39 is provided with a recess. The through electrode 34a is provided inside the through hole of the piezoelectric layer 6 and the first busbar 16, and inside the recess of the stopping layer 39.

The through electrode 34a of the other conducting portion 34 penetrates the piezoelectric layer 6 and the second busbar 17 of the first IDT electrode 12, and is connected to the stopping layer 39. To be more precise, the piezoelectric layer 6 and the second busbar 17 are provided with a through hole, and the stopping layer 39 is provided with a recess. The through electrode 34a is provided inside the through hole of the piezoelectric layer 6 and the second busbar 17, and inside the recess of the stopping layer 39.

Here, the first busbar 16 and the second busbar 17 need not be provided with the through holes. For example, the first busbar 16 and the second busbar 17 may be provided with recesses, or alternatively, need not be provided with the through holes or the recesses. Each stopping layer 39 need not be provided with the recess. The through electrode 34a of the conducting portion 34 need not be connected to the stopping layer 39.

In the present t example embodiment, the first IDT electrode 12 is a multilayer body. Specifically, for example, the first IDT electrode 12 includes a Ti layer, a Pt layer, a Ti layer, an AlCu layer, and a Ti layer are laminated in this order from the piezoelectric layer 6 side. Here, the materials of the first IDT electrode 12 are not limited to the above-described materials. For example, it is possible to use a metal such as, for example, Al, Cu, Pt, Au, Ag, Ti, Ni, Cr, Mo, or W, or an alloy including any of the these metals as a main component. In the present specification, the main component of the alloy means a component that exceeds about 50% by weight in the alloy. The first IDT electrode 12 may be made of a metal film or an alloy film including a single layer.

The stopping layer 39 includes a single-layered metal film. Specifically, the stopping layer 39 includes a Ti layer, for example. Here, the material of the stopping layer is not limited to the above-described material. For example, it is possible to use a metal such as, for example, Al, Cu, Pt, Au, Ag, Ti, Ni, Cr, Mo, and W, or an alloy including any of these metals as the main component. The stopping layer 39 may be a multilayer body or an alloy film including a single layer. Nonetheless, the stopping layers 39 do not always have to be provided.

The second IDT electrode 33 is a multilayer body. Specifically, for example, in the second IDT electrode 33, a Ti layer, an AlCu layer, and a Ti layer are laminated in this order from the piezoelectric layer 6 side. Here, the materials of the second IDT electrode 33 are not limited to the above-described materials. For example, it is possible to use a metal such as Al, Cu, Pt, Au, Ag, Ti, Ni, Cr, Mo, or W, or an alloy including any of these metals as a main component. The second IDT electrode 33 may include a metal film or an alloy film including a single layer.

As shown in FIG. 21, the first principal surface 6a of the piezoelectric layer 6 includes the alignment mark 38. The alignment mark 38 is used at the time of manufacturing the acoustic wave device. A material of the alignment mark 38 is preferably the same as the material of the first IDT electrode 12. Thus, it is possible to increase productivity. Nonetheless, the alignment mark 38 does not always have to be provided.

In the present example embodiment, the directions of polarization of the first lithium niobate layer 7 and the second lithium niobate layer 8 shown in FIG. 22 are inverted to each other in the thickness direction of the piezoelectric layer 6 as with the first example embodiment. The duty ratio of each of the first IDT electrode 12 and the second IDT electrode 33 is, for example, equal to or greater than about 0.6. Thus, the third harmonic wave can be strongly excited and the fundamental wave as the unnecessary wave can be reduced or prevented.

An example of a method of manufacturing the acoustic wave device according to the present example embodiment will be described below.

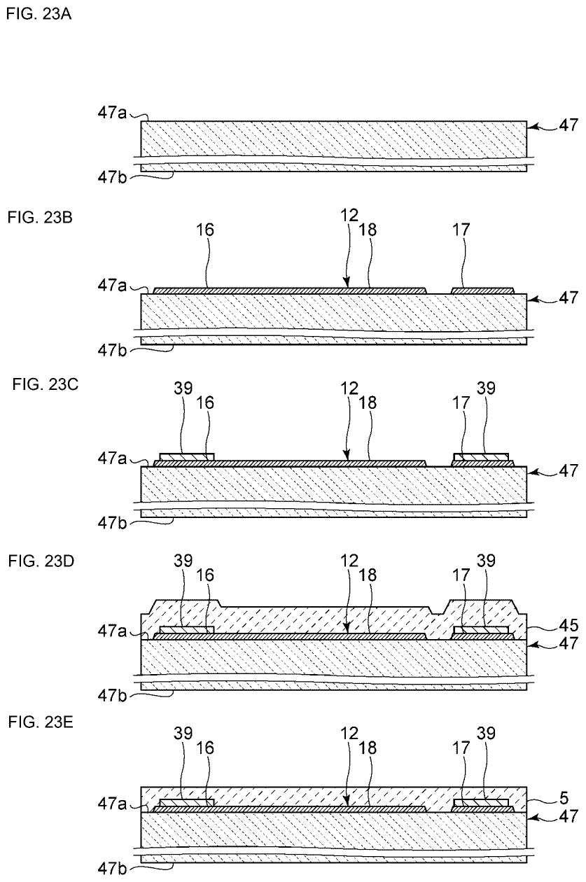

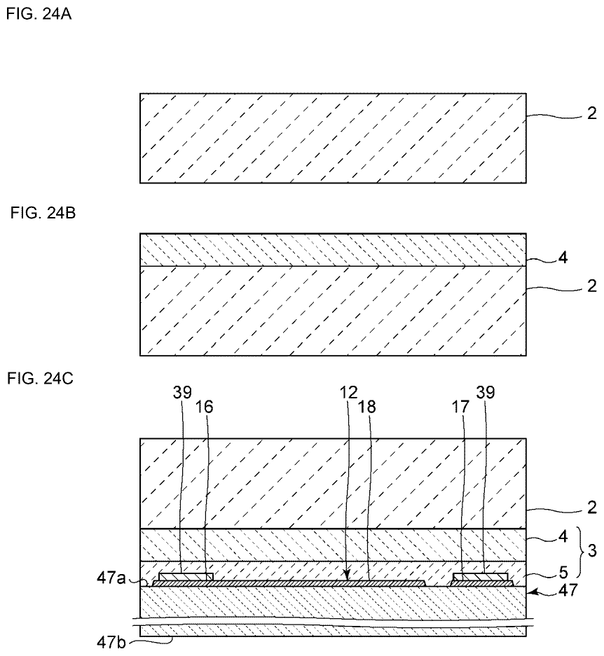

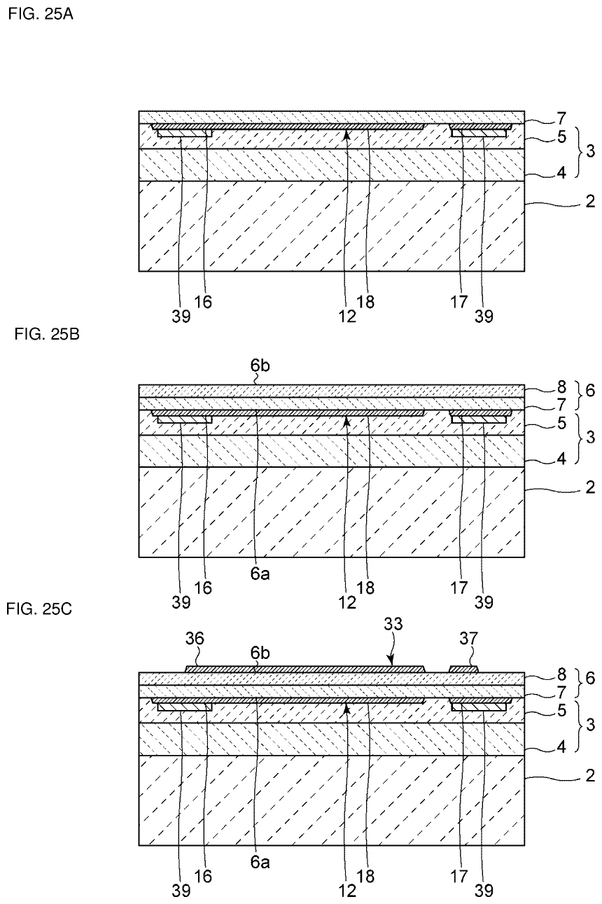

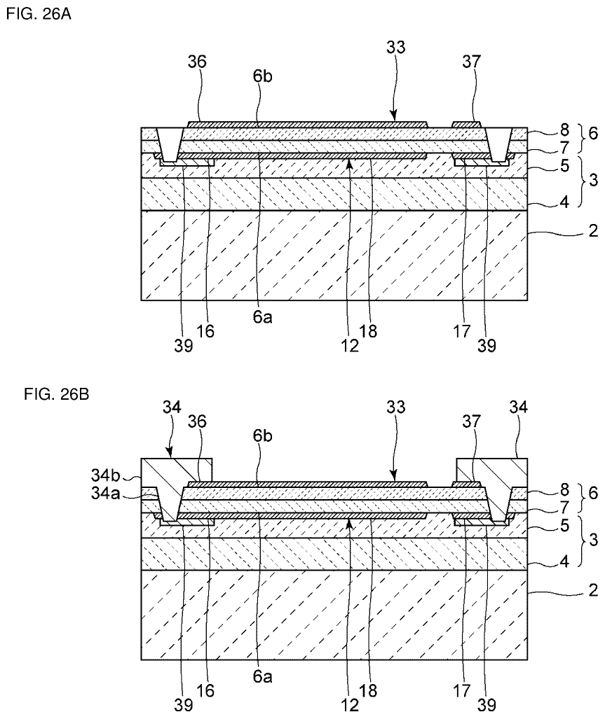

FIGS. 23A to 23E are schematic sectional views taken along the direction of extension of the electrode fingers for explaining steps until a step of providing the second layer of the intermediate layer in the example of the method of manufacturing the acoustic wave device according to the third example embodiment. FIGS. 24A to 24C are schematic sectional views taken along the direction of extension of the electrode fingers for explaining steps until a step of providing the intermediate layer in the example of the method of manufacturing the acoustic wave device according to the third example embodiment. FIGS. 25A to 25C are schematic sectional views taken along the direction of extension of the electrode fingers for explaining steps until a step of providing the second IDT electrode in the example of the method of manufacturing the acoustic wave device according to the third example embodiment. FIGS. 26A and 26B are schematic sectional views taken along the direction of extension of the electrode fingers for explaining steps until a step of providing the conducting portion in the example of the method of manufacturing the acoustic wave device according to the third example embodiment.

A first lithium niobate substrate 47 is prepared as shown in FIG. 23A. The first lithium niobate substrate 47 includes a third principal surface 47a and a fourth principal surface 47b. The third principal surface 47a and the fourth principal surface 47b are opposed to each other. Arithmetic surface roughness Ra of the third principal surface 47a is, for example, preferably equal to or below about 0.5 nm. In this case, the electrode can be suitably provided on the third principal surface 47a. On the other hand, the fourth principal surface 47b may be a rough surface. Here, the arithmetic surface roughness Ra in the present specification represents the arithmetic surface roughness Ra defined in JIS B 0601:2013.

Next, as shown in FIG. 23B, the first IDT electrode 12 is provided on the third principal surface 47a of the first lithium niobate substrate 47. At the same time, the respective reflectors and the alignment mark 38 shown in FIG. 21 are also provided on the third principal surface 47a. For example, it is possible to provide the first IDT electrode 12, the respective reflectors, and the alignment mark 38 by forming a metal film or an alloy film by using, for example, a sputtering method, a vacuum deposition method, or the like, and performing patterning by using a photolithography method and the like.

Next, as shown in FIG. 23C, the stopping layer 39 is provided on each of the first busbar 16 and the second busbar 17 of the first IDT electrode 12. For example, it is possible to provide the stopping layers 39 by forming a metal film or an alloy film by using, for example, the sputtering method, the vacuum deposition method, and the like, and performing patterning by using the photolithography method and the like.

Next, as shown in FIG. 23D, a dielectric film 45 is provided on the third principal surface 47a of the first lithium niobate substrate 47 so as to cover the first IDT electrode 12 and the stopping layers 39. The dielectric film 45 is a single-layered silicon nitride film, for example. Nonetheless, the material of the dielectric film 45 is not limited to silicon nitride. Alternatively, the dielectric film 45 may be a multilayer body. For example, it is possible to provide the dielectric film 45 in accordance with the sputtering method, the vapor deposition method, or the like, for example.

Next, planarization of the dielectric film 45 is performed. Grinding, a CMP (chemical mechanical polishing) method, or the like, for example, can be used for planarization of the dielectric film 45. In this way, the second layer 5 is obtained as shown in FIG. 23E. The second layer 5 is the second layer 5 of the intermediate layer 3 shown in FIG. 22. Here, for example, it is preferable to perform polishing and the like such that the arithmetic surface roughness Ra on the surface of the second layer 5 becomes equal to or below about 0.5 nm. This makes it easier to bond the second layer 5 to the first layer 4 in a subsequent step.

In the meantime, the support substrate 2 is prepared as shown in FIG. 24A. Next, the first layer 4 is provided on the support substrate 2 as shown in FIG. 24B. The first layer 4 is a single-layered silicon oxide film, for example. Nonetheless, the material of the first layer 4 is not limited to silicon oxide. Alternatively, the first layer 4 may be a multilayer body. For example, it is possible to provide the first layer 4 in accordance with the sputtering method, the vapor deposition method, or the like.

Here, for example, it is preferable to subject the surface of the first layer 4 to polishing or the like such that the arithmetic surface roughness Ra on the relevant surface becomes equal to or below about 0.5 nm. This makes it easier to bond the first layer 4 to the second layer 5 in the subsequent step.

Next, the first layer 4 is bonded to the second layer 5 as shown in FIG. 24C. For example, direct bonding, hydrophilic bonding, activated bonding, atomic diffusion bonding, metallic diffusion bonding, or the like can be used to bond the first layer 4 to the second layer 5.

Next, a thickness of the first lithium niobate substrate 47 is adjusted. More specifically, the thickness of the first lithium niobate substrate 47 is reduced by, for example, grinding or polishing the fourth principal surface 47b side of the first lithium niobate substrate 47. For example, grinding, the CMP method, an ion-slicing method, etching, or the like can be used to adjust the thickness of the first lithium niobate substrate 47. Thus, the first lithium niobate layer 7 is obtained as shown in FIG. 25A.

Here, for example, it is preferable to subject the surface of the first lithium niobate layer 7 to polishing or the like such that the arithmetic surface roughness Ra of the surface becomes equal to or below about 0.5 nm. This makes it easier to bond the first lithium niobate layer 7 to the second lithium niobate layer 8 in the next step.

Next, as shown in FIG. 25B, the first lithium niobate layer 7 is bonded to the second lithium niobate layer 8. For example, direct bonding, hydrophilic bonding, activated bonding, atomic diffusion bonding, metallic diffusion bonding, or the like can be used for bonding the first lithium niobate layer 7 to the second lithium niobate layer 8. Thus, the piezoelectric layer 6 is obtained.

Here, the first lithium niobate layer 7 may be bonded to a second lithium niobate substrate to obtain the piezoelectric layer 6 shown in FIG. 25B. The method shown as the example of the method of bonding the first lithium niobate layer 7 to the second lithium niobate layer 8 can be used to bond the first lithium niobate layer 7 to the second lithium niobate substrate. Thereafter, the second lithium niobate layer 8 may be obtained by adjusting a thickness of the second lithium niobate substrate. For example, grinding, the CMP method, the ion-slicing method, etching, or the like can be used to adjust the thickness of the second lithium niobate substrate.

Here, for example, it is preferable to subject the second principal surface 6b of the piezoelectric layer 6 to polishing and the like such that the arithmetic surface roughness Ra of the surface of the second lithium niobate layer 8, that is to say, the second principal surface 6b becomes equal to or below about 0.5 nm. In this case, the electrode can be suitably provided on the second principal surface 6b.

Next, as shown in FIG. 25C, the second IDT electrode 33 is provided on the second principal surface 6b of the piezoelectric layer 6. At the same time, the respective reflectors are provided on the second principal surface 6b. For example, it is possible to provide the second IDT electrode 33 and the respective reflectors by forming a metal film or an alloy film by using the sputtering method, the vacuum deposition method, or the like, and performing patterning by using the photolithography method and the like.

Next, as shown in FIG. 26A, the piezoelectric layer 6 as well as the first busbar 16 and the second busbar 17 in the first IDT electrode are provided with through holes. Each through hole can be provided by etching, for example. In the example shown in FIG. 26A, each stopping layer 39 is provided with the recess. The recesses are also provided by etching in the course of providing the through holes.

The through hole only needs to be provided on at least the piezoelectric layer 6 in this step. However, there may also be a case where the first busbar 16 and the second busbar 17 are also etched when the piezoelectric layer 6 is subjected to etching in order to provide the through hole, thus unintentionally providing the first busbar 16 and the second busbar 17 with the through holes.

Nonetheless, the stopping layers 39 are provided in the present example embodiment. The etching rate of the stopping layers 39 is equal to or below the etching rate of the first IDT electrode 12. Accordingly, the stopping layers 39 are less likely to be provided with through holes even when the first busbar 16 and the second busbar 17 are provided with the through holes by etching. Thus, it is possible to reduce or prevent etching of the intermediate layer 3 more reliably in the step of providing the through hole at least to the piezoelectric layer 6.

Next, as shown in FIG. 26B, the through electrode 34a is provided inside the through hole of the piezoelectric layer 6, inside the through hole of the first busbar 16 of the first IDT electrode 12, and inside the recess of one stopping layer 39 out of the pair of stopping layers 39. At the same time, the busbar connection electrode 34b is provided across the portion on the third busbar 36 of the second IDT electrode 33 and the portion on the second principal surface 6b of the piezoelectric layer 6. Thus, the one conducting portion 34 of the pair of conducting portions 34 is provided.

Similarly, the through electrode 34a is provided inside the through hole of the piezoelectric layer 6, inside the through hole of the second busbar 17 of the first IDT electrode 12, and inside the recess of the other stopping layer 39. At the same time, the busbar connection electrode 34b is provided across the portion on the fourth busbar 37 of the second IDT electrode 33 and the portion on the second principal surface 6b of the piezoelectric layer 6. Thus, the other conducting portion 34 is provided. The pair of conducting portions 34 can be provided at the same time.

In the case of providing the respective conducting portions 34, seed layers are provided on the respective busbars of the second IDT electrode 33, on the second principal surface 6b and inside the through hole of the piezoelectric layer 6, inside the through holes of the respective busbars of the first IDT electrode 12, and inside the respective recesses of the respective stopping layers 39. For example, it is possible to provide the seed layers by forming a metal film or an alloy film by using the sputtering method, the vacuum deposition method, or the like, and performing patterning by using the photolithography method and the like. Thereafter, the pair of conducting portions 34 can be provided by performing plating, for example.

In the above-described example of the method of manufacturing the acoustic wave device according to the third example embodiment, the first IDT electrode 12 is provided on the third principal surface 47a of the first lithium niobate substrate 47 as shown in FIG. 23B. Nonetheless, the manufacturing method is not limited thereto. An example of the method of manufacturing the acoustic wave device by using a temporary substrate according to the third example embodiment will be shown below. In the present specification, the temporary substrate is a substrate which is temporarily used at the time of manufacturing the acoustic wave device and is removed at the time of manufacturing the acoustic wave device.

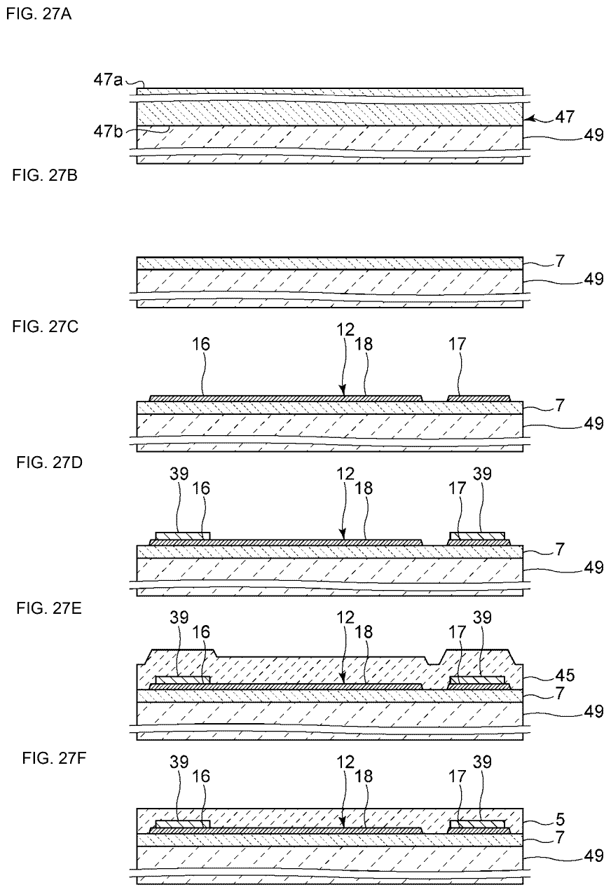

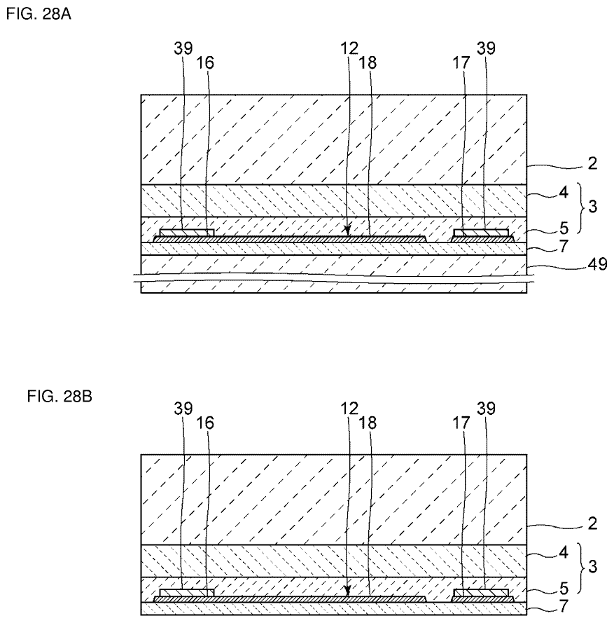

FIGS. 27A to 27F are schematic sectional views taken along the direction of extension of the electrode fingers for explaining steps until a step of providing the second layer of the intermediate layer in an example of the method of manufacturing the acoustic wave device using the temporary substrate according to the third example embodiment. FIGS. 28A and 28B are schematic sectional views taken along the direction of extension of the electrode fingers for explaining steps until a step of removing the temporary substrate in the example of the method of manufacturing the acoustic wave device using the temporary substrate according to the third example embodiment.

As shown in FIG. 27A, the first lithium niobate substrate 47 is provided on a temporary substrate 49. Of the third principal surface 47a and the fourth principal surface 47b of the first lithium niobate substrate 47, the fourth principal surface 47b is the principal surface on the temporary substrate 49 side. Alumina, sapphire, crystal, lithium tantalate, lithium niobate, glass, or the like, for example, can be used as a material of the temporary substrate 49. The temporary substrate 49 may be bonded to the first lithium niobate substrate 47 by using an appropriate bonding agent.

Next, the thickness of the first lithium niobate substrate 47 is adjusted. More specifically, the thickness of the first lithium niobate substrate 47 is reduced by, for example, grinding or polishing the third principal surface 47a side of the first lithium niobate substrate 47. Thus, a multilayer body including the first lithium niobate layer 7 and the temporary substrate 49 is obtained as shown in FIG. 27B. One of principal surfaces of the first lithium niobate layer 7 corresponds to the first principal surface 6a of the piezoelectric layer 6 shown in FIG. 22.

Next, as shown in FIG. 27C, the first IDT electrode 12 is provided on the above-described principal surface of the first lithium niobate layer 7 that corresponds to the first principal surface 6a. At the same time, the respective reflectors and the alignment mark 38 shown in FIG. 21 are also provided on this principal surface.

Next, as shown in FIG. 27D, the stopping layer 39 is provided on each of the first busbar 16 and the second busbar 17 of the first IDT electrode 12. Next, as shown in FIG. 27E, the dielectric film 45 is provided on the third principal surface 47a of the first lithium niobate substrate 47 so as to cover the first IDT electrode 12 and the stopping layers 39. Next, planarization of the dielectric film 45 is performed. In this way, the second layer 5 is obtained as shown in FIG. 27F. The second layer 5 is the second layer 5 of the intermediate layer 3 shown in FIG. 22.

In the meantime, the support substrate 2 is prepared in the same or substantially the same way as the step shown in FIG. 24A. Next, the first layer 4 is provided on the support substrate 2 in the same or substantially the same way as the step shown in FIG. 24B. Next, the first layer 4 is bonded to the second layer 5 as shown in FIG. 28A. Thus, the intermediate layer 3 is obtained.

Next, the temporary substrate 49 is removed by etching, for example. In the case where the temporary substrate 49 is bonded to the first lithium niobate layer 7 by using the bonding agent, the bonding agent may be removed by etching, for example. In this way, the temporary substrate 49 may be detached from the first lithium niobate layer 7. Thus, the multilayer body including the support substrate 2, the intermediate layer 3, and the first lithium niobate layer 7 is obtained as shown in FIG. 28B.

The subsequent steps may be performed in the same or substantially the same way as the steps shown in FIGS. 25B, 25C, 26A, and 26B.

Here, in the case of obtaining the piezoelectric layer 6 as shown in FIG. 25B, it is preferable to use a temporary substrate that is the same as or similar to the temporary substrate 49 shown in FIG. 27A and the like. More specifically, a multilayer body including the temporary substrate and the second lithium niobate substrate is prepared. The temporary substrate may be bonded to the second lithium niobate substrate by using an appropriate bonding agent. Next, a multilayer body including the temporary substrate and the second lithium niobate layer 8 is obtained by adjusting the thickness of the second lithium niobate substrate. Next, the second lithium niobate layer 8 in the multilayer body is bonded to the first lithium niobate layer 7.

Thereafter, the temporary substrate is removed. In the case where the above-described temporary substrate is bonded to the second lithium niobate layer 8 by using the bonding agent, the bonding agent may be removed by etching, for example. In this way, the temporary substrate may be detached from the second lithium niobate layer 8. Thus, the piezoelectric layer 6 is obtained.

Here, dielectric layers may be used in bonding the first lithium niobate layer 7 to the second lithium niobate layer 8, for example. In this case, a first dielectric layer may be provided on the surface of the first lithium niobate layer 7. Meanwhile, a second dielectric layer may be provided on the surface of the second lithium niobate layer 8. Next, the first dielectric layer may be bonded to the second dielectric layer. In this case, the piezoelectric layer 26 is obtained as the multilayer body in the second example embodiment shown in FIG. 20, which includes the first lithium niobate layer 7, the dielectric layer 25, and the second lithium niobate layer 8.

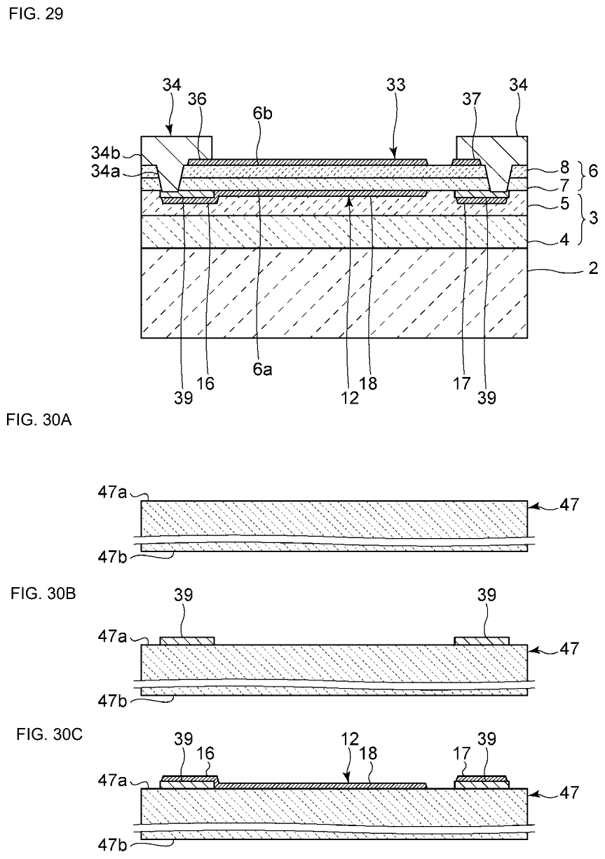

In the third example embodiment, the respective busbars and the respective stopping layers 39 of the first IDT electrode 12 are laminated in this order from the piezoelectric layer 6 side at the portion where the respective busbars and the respective stopping layers 39 are laminated. Nonetheless, the present invention is not limited to this structure. For example, in a first modification of the third example embodiment shown in FIG. 29, the one stopping layer 39 of the pair of stopping layers 39 and the first busbar 16 of the first IDT electrode 12 are laminated in this order from the piezoelectric layer 6 side. Similarly, the other stopping layer 39 and the second busbar 17 are laminated in this order from the piezoelectric layer 6 side.

The stopping layer 39 is provided with the recess. The piezoelectric layer 6 is provided with the through hole. The through electrode 34a in the conducting portion 34 is provided inside the through hole of the piezoelectric layer 6 and inside the recess of the stopping layer 39. As described above, the through electrode 34a penetrates the piezoelectric layer 6. On the other hand, the through electrode 34a does not penetrate the stopping layer 39.

The respective through electrodes 34a in the respective conducting portions 34 are not connected to the respective busbars of the first IDT electrode 12. Nonetheless, the one stopping layer 39 of the pair of stopping layers 39 is electrically connected to the first busbar 16 of the first IDT electrode 12. The other stopping layer 39 is electrically connected to the second busbar 17 of the first IDT electrode 12. Accordingly, the one conducting portion 34 of the pair of conducting portions 34 electrically connects the first busbar 16 of the first IDT electrode 12 and the third busbar 36 of the second IDT electrode 33. The other conducting portion 34 electrically connects the second busbar 17 of the first IDT electrode 12 and the fourth busbar 37 of the second IDT electrode 33.

The acoustic wave device of the present modification is structured the same or substantially the same as the acoustic wave device of the third example embodiment except for the orders of lamination of the respective busbars and the respective stopping layers 39 of the first IDT electrode 12 and that the through electrodes 34a do not penetrate the respective busbars. Thus, the third harmonic wave can be strongly excited and the fundamental wave as the unnecessary wave can be reduced or prevented in the present modification as well.

In order to obtain the acoustic wave device of the present modification, the first lithium niobate substrate 47 is prepared as shown in FIG. 30A, for example. Next, as shown in FIG. 30B, the pair of stopping layers 39 are provided on the third principal surface 47a of the first lithium niobate substrate 47.

Next, as shown in FIG. 30C, the first IDT electrode 12 is provided across portions on the pair of stopping layers 39 and on a portion of the third principal surface 47a of the first lithium niobate substrate 47. In this instance, the first busbar 16 of the first IDT electrode 12 is provided on the one stopping layer 39 of the pair of stopping layers 39. The second busbar 17 is provided on the other stopping layer 39.

Thereafter, the multilayer body including the support substrate 2, the intermediate layer 3, and the piezoelectric layer 6, and the second IDT electrode 33 are provided in the same or substantially the same way as the steps shown in FIGS. 23D, 23E, 24A to 24C, and 25A to 25C.

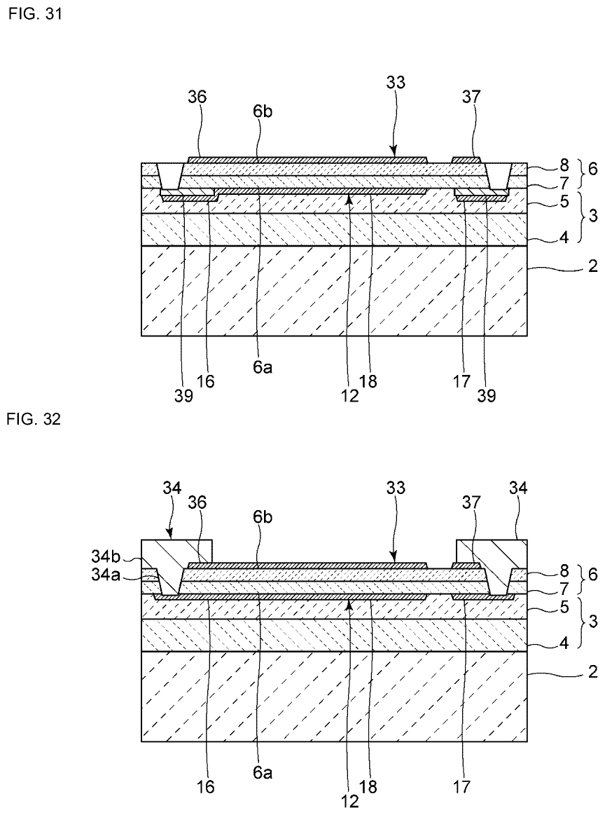

Next, the piezoelectric layer 6 is provided with the through holes as shown in FIG. 31. The respective through holes can be provided by etching, for example. In the example shown in FIG. 31, the respective stopping layers 39 are provided with the recesses. The recesses are also provided by etching in the case of providing the through holes.

In the present modification, the first principal surface 6a of the piezoelectric layer 6 is provided with the stopping layers 39. When the piezoelectric layer 6 is provided with the through holes by etching, the through holes are less likely to be provided on the stopping layers 39. Accordingly, it is possible to more reliably reduce or prevent etching of the intermediate layer 3 in the step of providing the piezoelectric layer 6 with the through holes.

Next, the through electrode 34a shown in FIG. 29 is provided inside the through hole of the piezoelectric layer 6 and inside the recess of the one stopping layer 39 of the pair of stopping layers 39. At the same time, the busbar connection electrode 34b is provided across the portion on the third busbar 36 of the second IDT electrode 33 and the portion on the second principal surface 6b of the piezoelectric layer 6. Thus, the one conducting portion 34 of the pair of conducting portions 34 is provided.

Similarly, the through electrode 34a is provided inside the through hole of the piezoelectric layer 6 and inside the recess of the other stopping layer 39. At the same time, the busbar connection electrode 34b is provided across the portion on the fourth busbar 37 of the second IDT electrode 33 and the portion on the second principal surface 6b of the piezoelectric layer 6. Thus, the other conducting portion 34 is provided. The pair of conducting portions 34 can be provided simultaneously.

Nonetheless, the stopping layers 39 do not always have to be provided. For example, the stopping layers are not provided in a second modification of the third example embodiment shown in FIG. 32. Each of the first busbar 16 and the second busbar 17 of the first IDT electrode 12 is provided with a recess. The piezoelectric layer 6 is provided with the through holes. The through electrode 34a in each conducting portion 34 is provided inside the through hole of the piezoelectric layer 6 and inside the recess of each busbar. As described above, the through electrode 34a penetrates the piezoelectric layer 6. On the other hand, the through electrode 34a does not penetrate each busbar. Here, each busbar does not always have to be provided with the recess.

The one conducting portion 34 of the pair of conducting portions 34 connects the first busbar 16 of the first IDT electrode 12 and the third busbar 36 of the second IDT electrode 33. The other conducting portion 34 connects the second busbar 17 of the first IDT electrode 12 and the fourth busbar 37 of the second IDT electrode 33.

The acoustic wave device of the present modification is structured the same or substantially the same as the acoustic wave device of the third example embodiment except that the stopping layers are not provided and that the through electrodes 34a do not penetrate the respective busbars in the first IDT electrode 12. Thus, the third harmonic wave can be strongly excited and the fundamental wave as the unnecessary wave can be reduced or prevented in the present modification as well.

In order to obtain the acoustic wave device of the present modification, the first IDT electrode 12 is provided on the third principal surface 47a of the first lithium niobate substrate 47 in the same or substantially the same way as the steps shown in FIGS. 23A and 23B, for example. Thereafter, the multilayer body including the support substrate 2, the intermediate layer 3, and the piezoelectric layer 6, and the second IDT electrode 33 are provided in the same or substantially the same way as the steps shown in FIGS. 23D, 23E, 24A to 24C, and 25A to 25C without providing the stopping layers.

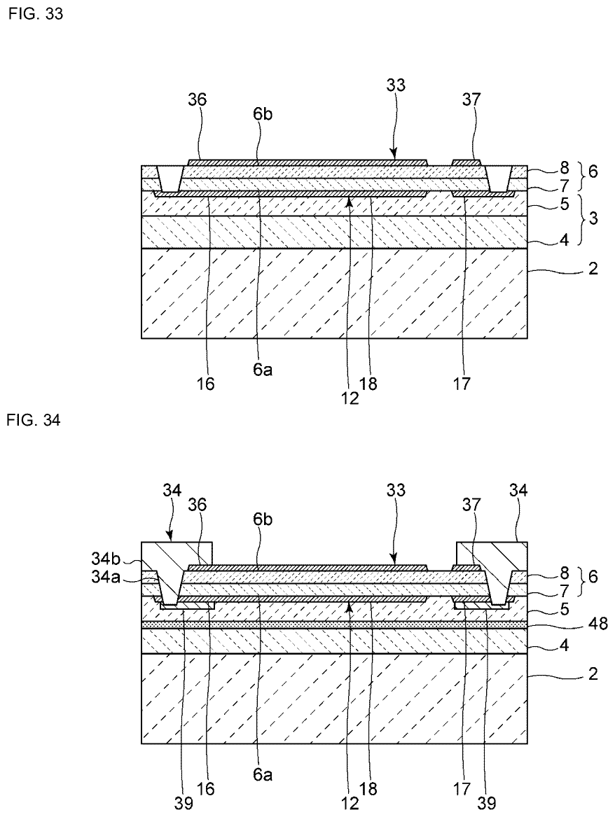

Next, the piezoelectric layer 6 is provided with the through holes as shown in FIG. 33. The respective through holes can be provided by etching, for example. In this instance, it is preferable to perform adjustment of the etching rate and the like in order not to provide the respective busbars of the first IDT electrode 12 with the through holes. In the example shown in FIG. 33, each busbar of the first IDT electrode 12 is provided with a recess. The recess is provided by, for example, etching at the time of providing the through holes. Nonetheless, each busbar is prevented from being provided with the through hole. Accordingly, it is possible to reduce or prevent etching of the intermediate layer 3 in the step of providing the piezoelectric layer 6 with the through holes.

Next, the through electrode 34a shown in FIG. 32 is provided inside the through hole of the piezoelectric layer 6 and inside the recess of the first busbar 16 of the first IDT electrode 12. At the same time, the busbar connection electrode 34b is provided across the portion on the third busbar 36 of the second IDT electrode 33 and the portion on the second principal surface 6b of the piezoelectric layer 6. Thus, the one conducting portion 34 of the pair of conducting portions 34 is provided.

Similarly, the through electrode 34a is provided inside the through hole of the piezoelectric layer 6 and inside the recess of the second busbar 17 of the first IDT electrode 12. At the same time, the busbar connection electrode 34b is provided across the portion on the fourth busbar 37 of the second IDT electrode 33 and the portion on the second principal surface 6b of the piezoelectric layer 6. Thus, the other conducting portion 34 is provided. The pair of conducting portions 34 can be provided simultaneously.

In the third example embodiment shown in FIG. 22, the first layer 4 is directly bonded to the second layer 5. Nonetheless, the present invention is not limited thereto. For example, in a third modification of the third example embodiment shown in FIG. 34, a bonding layer 48 is provided between the first layer 4 and the second layer 5. The first layer 4 is bonded to the second layer 5 by using the bonding layer 48. For example, a dielectric body, a metal, a semiconductor, or a resin can be used as a material of the bonding layer 48.

An acoustic wave device of the present modification is structured the same or substantially the same as the acoustic wave device of the third example embodiment except for the bonding layer 48 being provided. Thus, the third harmonic wave can be strongly excited and the fundamental wave as the unnecessary wave can be reduced or prevented in the present modification as well.

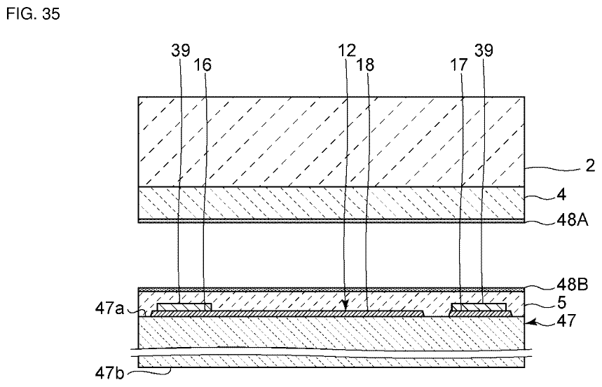

In order to obtain the acoustic wave device of the present modification, the same or substantially the same steps as the steps shown in FIGS. 23A to 23E, 24A, and 24B may be performed. Next, as shown in FIG. 35, a first bonding layer 48A is provided on the surface of the first layer 4. A second bonding layer 48B is provided on the surface of the second layer 5. The first bonding layer 48A and the second bonding layer 48B are made of the dielectric body, the metal, the semiconductor, or the resin, for example.

Next, the first bonding layer 48A is bonded to the second bonding layer 48B. Thus, a multilayer body including the support substrate 2, the first layer 4, the bonding layer 48 shown in FIG. 34, the second layer 5, and the first lithium niobate substrate 47 is obtained. The subsequent steps may be performed in the same or substantially the same way as those in the example of the above-described method of manufacturing the acoustic wave device according to the third example embodiment.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support substrate;
a piezoelectric layer on the support substrate, and including at least one layer of a lithium niobate layer and a first principal surface and a second principal surface opposed to each other; and
a first interdigital transducer (IDT) electrode on the first principal surface of the piezoelectric layer, and a second IDT electrode on the second principal surface of the piezoelectric layer; wherein
each of the first IDT electrode and the second IDT electrode includes a plurality of electrode fingers and a duty ratio of each of the first IDT electrode and the second IDT electrode is equal to or greater than about 0.6; and
directions of polarization of the piezoelectric layer are inverted in a thickness direction of the piezoelectric layer.

2. The acoustic wave device according to claim 1, wherein
the piezoelectric layer includes a first lithium niobate layer, and a second lithium niobate layer laminated directly or indirectly on the first lithium niobate layer;
of the first lithium niobate layer and the second lithium niobate layer, the first lithium niobate layer is located on a support substrate side, the first lithium niobate layer includes the first principal surface of the piezoelectric layer, and the second lithium niobate layer includes the second principal surface of the piezoelectric layer; and
a direction of polarization of the first lithium niobate layer and a direction of polarization of the second lithium niobate layer are mutually opposite directions.

3. The acoustic wave device according to claim 2, wherein, where Euler angles in the first lithium niobate layer are denoted as (φ1, θ1, ψ1) and n is denoted as a natural number, the value ψ1 in the Euler angles of the first lithium niobate layer is in a range within about 0°±5°, the value θ1 in the Euler angles satisfies about −90°±180°×n≤θ1≤about −45°+180°×n, and the value ψ1 in the Euler angles is in a range within about 0°±5°.

4. The acoustic wave device according to claim 2, wherein a thickness of the first lithium niobate layer is larger than a thickness of the second lithium niobate layer.

5. The acoustic wave device according to claim 2, wherein, when one that is not larger of a wavelength defined by an electrode finger pitch of the first IDT electrode and a wavelength defined by an electrode finger pitch of the second IDT electrode is denoted as a wavelength λ, a total thickness of the first lithium niobate layer and the second lithium niobate layer is equal to or greater than about 0.15λ.

6. The acoustic wave device according to claim 2, wherein the first lithium niobate layer and the second lithium niobate layer are directly laminated.

7. The acoustic wave device according to claim 2, wherein the piezoelectric layer includes a dielectric layer between the first lithium niobate layer and the second lithium niobate layer.

8. The acoustic wave device according to claim 1, wherein the first IDT electrode includes at least a main electrode layer being a layer that exceeds about 50% by weight in a layer structure, and the second IDT electrode includes at least a main electrode layer being a layer that exceeds about 50% by weight in a layer structure;
when a wavelength defined by an electrode finger pitch of the first IDT electrode is denoted as λ1, a thickness of the main electrode layer in the first IDT electrode is equal to or below about 0.04λ1; and
when a wavelength defined by an electrode finger pitch of the second IDT electrode is denoted as λ2, a thickness of the main electrode layer in the second IDT electrode is equal to or below about 0.04λ2.

9. The acoustic wave device according to claim 1, wherein
the first IDT electrode is located on a support substrate side; and
a thickness of the first IDT electrode is smaller than a thickness of the second IDT electrode.

10. The acoustic wave device according to claim 1, wherein
the first IDT electrode is located on a support substrate side; and
a density of a material included in the first IDT electrode is higher than a density of a material included in the second IDT electrode.

11. The acoustic wave device according to claim 1, wherein
the support substrate includes a silicon substrate;
a plane orientation of the support substrate is (111); and
when Euler angles of the support substrate are denoted as (φ_{Si}, θ_{Si}, ψ_{Si}) and n is a natural number, the value ψ_{Si} in the Euler angles of the support substrate is in any of a range within about (0°+120°×n)±5° and a range within about (60°+120°×n)±5°.

12. The acoustic wave device according to claim 1, wherein
the support substrate includes a silicon substrate;
a plane orientation of the support substrate is (110); and
when Euler angles of the support substrate are denoted as (φ_{Si}, θ_{Si}, ψ_{Si}) and n is a natural number, the value ψ_{Si} in the Euler angles of the support substrate satisfies about 155°+180°×n≤ψ_{Si}≤about 205°+180°×n.

13. The acoustic wave device according to claim 1, wherein a difference between a minimum value and a maximum value of impedance in a mode generated equal to or greater than about 6000 MHz and equal to or below about 7000 MHz is equal to or below about 5 dB.

14. The acoustic wave device according to claim 1, further comprising an intermediate layer between the support substrate and the piezoelectric layer.

15. The acoustic wave device according to claim 14, wherein the intermediate layer includes a first layer on the support substrate and a second layer on the first layer.

16. The acoustic wave device according to claim 15, wherein the first layer includes silicon nitride, and the second layer includes silicon oxide.

17. The acoustic wave device according to claim 1, wherein the duty ratio of each of the first IDT electrode and the second IDT electrode is equal to or greater than about 0.7.

18. The acoustic wave device according to claim 1, wherein the duty ratio of each of the first IDT electrode and the second IDT electrode is equal to or greater than about 0.8.

19. The acoustic wave device according to claim 1, wherein the duty ratio of each of the first IDT electrode and the second IDT electrode is equal to or greater than about 0.9.

20. The acoustic wave device according to claim 1, wherein
the first IDT electrode include a first busbar connected to an end of each of the plurality of electrode fingers of the first IDT electrode; and
the second IDT electrode includes a second busbar connected to an end of each of the plurality of electrode fingers of the second IDT electrode.
